(19) United States
(12) Patent Application Publication
(10) Pub. No.: US 2025/0098164 A1
(43) Pub. Date: Mar. 20, 2025

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventors: Toshimichi NISHIMURA, Yokkaichi (JP); Yosuke TAKEUCHI, Yokkaichi (JP)

(73) Assignee: Kioxia Corporation, Tokyo (JP)

(21) Appl. No.: 18/826,326

(22) Filed: Sep. 6, 2024

(30) Foreign Application Priority Data
Sep. 20, 2023 (JP) 2023-153890

(51) Int. Cl. H10B 43/27

(52) U.S. Cl. CPC H10B 43/27

(57) ABSTRACT

According to one embodiment, a semiconductor memory device includes first and second stacked bodies. In each of the first and second stacked bodies, conductive layers and insulating layers are alternately stacked one by one. The semiconductor memory device includes first and second bridging members. The first bridging member penetrates the first stacked body and connects first interlayer insulating films covering a first staircase part on both sides. The first bridging member is provided on an upper end of a first platy member. The second bridging member penetrates the second stacked body and connects second interlayer insulating films covering a second staircase part on both sides. The second bridging member is provided on an upper end of a second platy member. Lower ends of the first and second bridging members are positioned above uppermost conductive layers of the first and second stacked bodies, respectively.

### CROSS-REFERENCE TO RELATED APPLICATIONS

This application is based upon and claims the benefit of priority from Japanese Patent Application No. 2023-153890, filed on Sep. 20, 2023, the entire contents of which are incorporated herein by reference.

### FIELD

Embodiments described herein relate generally to a semiconductor memory device and a method of manufacturing a semiconductor memory device.

### BACKGROUND

A semiconductor memory device such as a three-dimensional nonvolatile memory may include a stacked body in which conductive layers and insulating layers are alternately stacked one by one. The stacked body is formed by forming grooves in insulating layers and sacrificial layers formed of different materials, causing a process liquid to penetrate into the insulating layers and the sacrificial layers from the groove, and replacing the sacrificial layers with the conductive layers.

Incidentally, in the process of forming the semiconductor memory device, deflection and inclination of the layers may occur due to stress generated from various materials. In order to reduce the deflection and the inclination, a bridging member that can support the materials of both sides may be formed above the groove. As the number of layers stacked in the stacked body increases, the stress generated in the layers increases, and thus thickening of the bridging member is required.

However, if the bridging member is thickened up to a depth at which the conductive layers are formed, formation failure of the conductive layers may occur during the replacement of the sacrificial layers with the conductive layers. As a result, the distance between a metal layer formed in the groove and the conductive layer decreases, which may decrease voltage resistance performance.

### BRIEF DESCRIPTION OF THE DRAWINGS

FIG. 1 is a partial top view illustrating a schematic configuration of a semiconductor memory device according to a first embodiment;

FIG. 2A is a cross-sectional view illustrating a detailed configuration of a cell array region according to the first embodiment;

FIGS. 2Ba and 2Bb are cross-sectional views illustrating a detailed configuration of a staircase region according to the first embodiment;

FIGS. 3A and 3B are diagrams illustrating a positional relationship between a first bridging member and a second bridging member according to the first embodiment;

FIGS. 4Aa to 4Bd are diagrams illustrating part of a procedure of a method of forming the semiconductor memory device according to the first embodiment;

FIGS. 5Ae to 5Bg are diagrams illustrating part of a procedure of a method of manufacturing the semiconductor memory device according to the first embodiment;

FIGS. 6Ah to 6Bi are diagrams illustrating part of the procedure of the method of manufacturing the semiconductor memory device according to the first embodiment;

FIGS. 7Aj to 7Bk are diagrams illustrating part of the procedure of the method of manufacturing the semiconductor memory device according to the first embodiment;

FIGS. 8Al to 8Bm are diagrams illustrating part of the procedure of the method of manufacturing the semiconductor memory device according to the first embodiment;

FIGS. 9An to 9Bo are diagrams illustrating part of the procedure of the method of manufacturing the semiconductor memory device according to the first embodiment;

FIGS. 10Ap to 10Bp are diagrams illustrating part of the procedure of the method of manufacturing the semiconductor memory device according to the first embodiment;

FIGS. 11A to 11D are cross-sectional views illustrating a detailed configuration of a cell array region of a semiconductor memory device according to Comparative Example;

FIGS. 12A and 12B are cross-sectional views illustrating a detailed configuration of a cell array region of a semiconductor memory device according to a modification example of the first embodiment;

FIGS. 13A to 13D are diagrams illustrating part of a procedure of a method of manufacturing the semiconductor memory device according to the modification example of the first embodiment;

FIG. 14A is a partial top view illustrating a configuration example of a semiconductor memory device according to a second embodiment;

FIGS. 14Ba to 14Bb are cross-sectional views illustrating the configuration example of the semiconductor memory device according to the second embodiment;

FIGS. 15A and 15B are diagrams illustrating a positional relationship between a first bridging member and a second bridging member according to the second embodiment;

FIGS. 16Aa to 16Cc are diagrams illustrating part of a procedure of a method of manufacturing the semiconductor memory device according to the second embodiment;

FIGS. 17Ad to 17Ce are diagrams illustrating part of a procedure of a method of manufacturing the semiconductor memory device according to the second embodiment;

FIGS. 18Af to 18Bg are diagrams illustrating part of the procedure of the method of manufacturing the semiconductor memory device according to the second embodiment;

FIGS. 19Ah to 19Ch are diagrams illustrating part of the procedure of the method of manufacturing the semiconductor memory device according to the second embodiment;

FIGS. 20Aj to 20Bj are diagrams illustrating part of the procedure of the method of manufacturing the semiconductor memory device according to the second embodiment;

FIG. 21 is a diagram illustrating a disposition example of a first bridging member according to a first modification example of the second embodiment; and

FIG. 22 is a diagram illustrating a disposition example of a first bridging member according to a second modification example of the second embodiment.

### DETAILED DESCRIPTION

According to one embodiment of the present disclosure, a semiconductor memory device includes a first stacked body, a first interlayer insulating film, a second stacked body, a second interlayer insulating film, a first platy member, a second platy member, a first bridging member, and a second bridging member. In the first stacked body, first conductive layers and first insulating layers are alternately stacked one by one. The first conductive layers include a first staircase part in a staircase shape extending in a first direction intersecting with a stacking direction of the first conductive layers. The first interlayer insulating film covers the first staircase part. In the second stacked body, second conductive layers and second insulating layers are alternately stacked one by one. The second stacked body is provided above the first stacked body. The second conductive layers include a second staircase part in a staircase shape continuous to the first staircase part in the first direction. The second interlayer insulating film covers the second staircase part. The first platy member extends in the first direction and penetrates the first stacked body in the stacking direction. The second platy member extends in the first direction and penetrating the second stacked body in the stacking direction. The second platy member is connected to an upper end of the first platy member. The first bridging member is provided on the upper end of the first platy member. The first bridging member connects the first interlayer insulating films on both sides of the first platy member. The second bridging member is provided on an upper end of the second platy member. The second bridging member connects the second interlayer insulating films on both sides of the second platy member. Lower ends of the first and second bridging members are positioned above uppermost first and second conductive layers in the first and second stacked bodies, respectively.

Hereinafter, a semiconductor memory device according to any one of embodiments and a method of manufacturing the semiconductor memory device will be described in detail with reference to the accompanying drawings. The present invention is not limited to these embodiments.

### First Embodiment

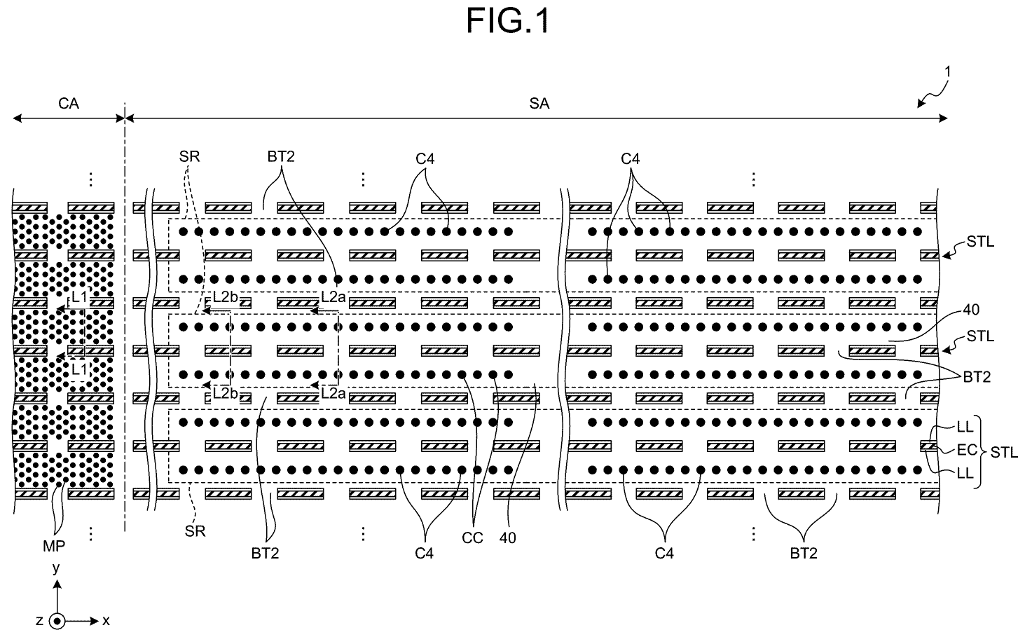

A configuration example of a semiconductor memory device 1 according to a first embodiment will be described with reference to FIGS. 1 to 3B. The semiconductor memory device 1 according to the present embodiment includes a cell array region and a staircase region.

FIG. 1 is a partial top view illustrating a schematic configuration of the semiconductor memory device 1 according to a first embodiment. FIG. 1 illustrates part of a cell array region CA and part of a staircase region SA of the semiconductor memory device 1. Upper wirings, plugs, or the like are provided on the cell array region CA and the staircase region SA, which are not illustrated in FIG. 1.

In the present specification, both of an x direction and a y direction are directions along directions of surfaces of a plurality of conductive layers described below, and the x direction and the y direction are orthogonal to each other. In addition, a direction intersecting with the x direction and the y direction, namely, a stacking direction of the plurality of conductive layers is a z direction. The x direction is an example of the first direction, and the y direction is an example of the second direction.

The cell array region CA includes a stacked body (described below) in which conductive layers and insulating layers are alternately stacked one by one, and a plurality of memory pillars MP that penetrate the stacked body in the z direction. The memory pillars MP are arranged in a lattice shape in an xy plane in the drawing, and extend in the z direction in the drawing.

The staircase region SA includes staircase parts SR. In the present embodiment, the staircase parts SR each have a predetermined length in the x direction. The staircase parts SR extending in the x direction are disposed away from each other at a predetermined distance in the y direction.

In the staircase part SR, the stacked body is processed in a staircase shape such that each of the conductive layers forms a terrace surface (tread surface), and a second interlayer insulating film 40 is formed at least above the staircase part SR. The second interlayer insulating film 40 is, for example, a silicon oxide layer. In the staircase part SR, a contact CC that penetrates the second interlayer insulating film 40 is connected to the terrace surface is provided. In the present specification, a direction in which the terrace surface of each of the steps of the staircase part SR faces is defined as an upper direction.

In the cell array region CA and the staircase region SA, platy members STL that divide each of these regions are formed. Each of the platy members STL crosses the cell array region CA and the staircase region SA in the x direction, extends in the z direction in the drawing, and terminates in a source line (described below). In addition, each of the platy members STL includes a liner layer LL and a conductive member EC disposed inside the liner layer LL. The liner layer LL is, for example, a silicon oxide layer. The conductive member EC is a conductive material, and examples thereof include a tungsten layer, a tungsten nitride layer, a titanium layer, a titanium nitride layer, a molybdenum layer, and a molybdenum nitride layer. The platy member STL connected to the source line (described below) in the conductive member EC functions as a source line contact. On an upper end of the platy members STL, second bridging members BT2 that are intermittently provided in a longitudinal direction (x direction) of the platy member STL are provided.

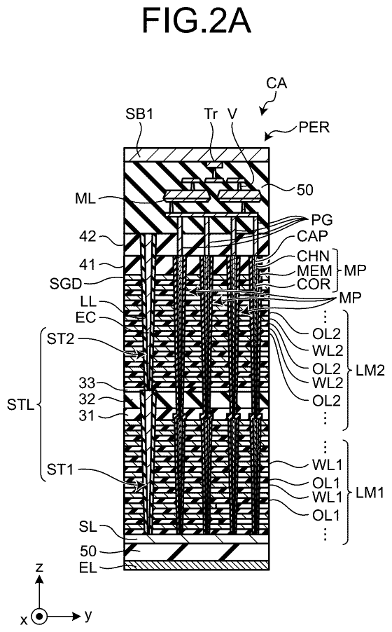

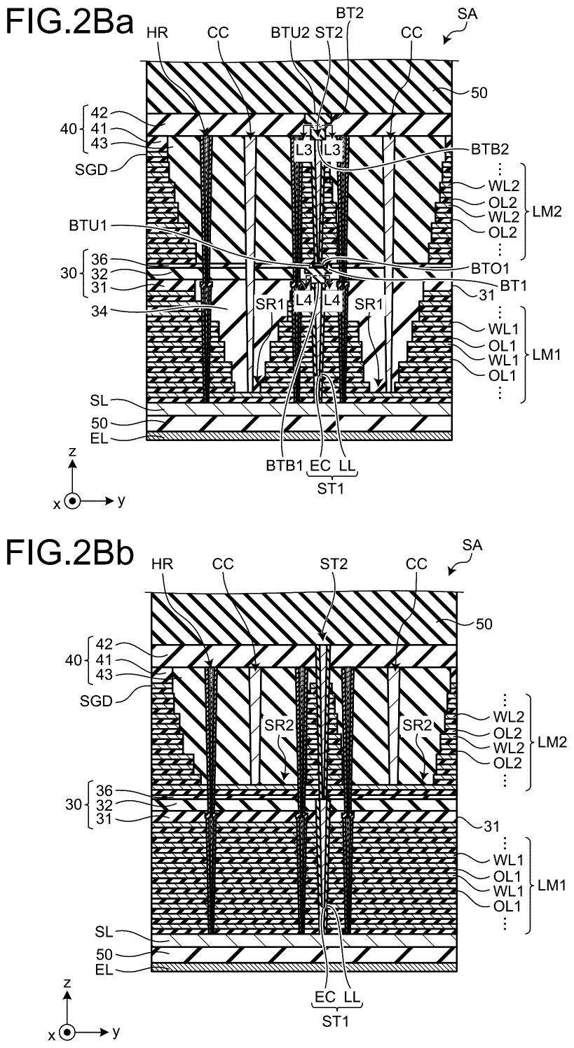

Next, the details of the cell array region CA and the staircase region SA will be described using FIGS. 2A to 2Bb. FIG. 2A is a cross-sectional view illustrating a detailed configuration of the cell array region CA according to the first embodiment. More specifically, FIG. 2A is a yz cross-sectional view taken along line L1-L1 of FIG. 1. In addition, FIGS. 2Ba and 2Bb are cross-sectional views illustrating a detailed configuration of the staircase region SA according to the first embodiment. More specifically, FIG. 2Ba is a yz cross-sectional view taken along line L2a-L2a of FIG. 1, and FIG. 2Bb is a yz cross-sectional view taken along line L2b-L2b of FIG. 1.

As illustrated in FIGS. 2A to 2Bb, the semiconductor memory device 1 includes a first stacked body LM1 on a source line SL and includes a second stacked body LM2 above the first stacked body LM1.

The source line SL is, for example, a conductive polycrystal silicon layer. The source line SL is disposed on an electrode film EL through an insulating layer 50. Multiple plugs (not illustrated) are disposed in the insulating layer 50, and electrical connection between the source line SL and the electrode film EL is ensured through the plugs. As a result, a source potential is applied from the outside of the semiconductor memory device 1 to the source line SL through the electrode film EL and the plugs.

The first stacked body LM1 has a configuration that conductive layers WL1 and insulating layers OL1 are alternately stacked one by one. The second stacked body LM2 has a configuration that conductive layers WL2 and insulating layers OL2 are alternately stacked one by one. Examples of the conductive layers WL1 and WL2 include a tungsten layer, a tungsten nitride layer, a titanium layer, a titanium nitride layer, a molybdenum layer, and a molybdenum nitride layer. Examples of the insulating layers OL1 and OL2 include a silicon oxide layer and an aluminum oxide layer. The conductive layer WL1 is an example of the first conductive layer, and the insulating layer OL1 is an example of the first insulating layer. In addition, the conductive layer WL2 is an example of the second conductive layer, and the insulating layer OL2 is an example of the second insulating layer.

FIGS. 2A to 2Bb illustrate the conductive layers WL1 and WL2 and the insulating layers OL1 and OL2 of appropriate numbers for the description. The numbers of the conductive layers WL1 and WL2 are not limited to the example illustrated in the drawing and are appropriately determined. For example, forty-eight (48) conductive layers, sixty-four (64) conductive layers, or ninety-six (96) conductive layers may be formed.

An insulating layer 31, an insulating layer 32, and an insulating layer 33 are formed in this order between the first stacked body LM1 and the second stacked body LM2 to cover the first stacked body LM1. The insulating layers 31 to 33 are configured to include, for example, an insulating material such as a silicon oxide layer. In addition, an insulating layer 41 and an insulating layer 42 are formed in this order above the second stacked body LM2 to cover the second stacked body LM2. The insulating layers 41 and 42 are configured to include, for example, an insulating material such as a silicon oxide layer.

As illustrated in FIG. 2A, in the cell array region CA, the memory pillars MP and the platy members STL are formed.

The memory pillar MP penetrates the first stacked body LM1, the insulating layers 31 to 33, the second stacked body LM2, and the insulating layer 41 in the z direction, and terminates in the source line SL. The memory pillar MP has a substantially cylindrical shape, includes a core layer COR, a channel layer CHN, and a memory film MEM that are concentrically formed in order from the center toward the outside, and includes a cap layer CAP in an upper part. Here, the core layer COR is, for example, silicon oxide, and the channel layer CHN and the cap layer CAP are, for example, conductive polycrystal silicon or amorphous silicon. In addition, the memory film MEM includes a tunnel insulating layer, a charge storage layer, and a block insulating layer (all of which are not illustrated) that are sequentially formed in a direction from the center toward the outside of the memory pillar MP. The tunnel insulating layer and the block insulating layer are, for example, silicon oxide layers, and the charge storage layer is, for example, a silicon nitride layer.

In each of the conductive layer WL1 and the conductive layer WL2, a memory cell (not illustrated) is formed in a part facing the memory film MEM of the memory pillar MP. In this case, each of the conductive layer WL1 and the conductive layers WL2 functions as a word line. Note that, in the lowermost and uppermost conductive layers among the conductive layer WL1 and the conductive layer WL2, a part facing the memory pillar MP may function as a select transistor. Therefore, for example, the uppermost conductive layer WL2 in the second stacked body LM2 may function as a drain-side select gate line SGD.

A plug PG is provided on the memory pillar MP. The plug PG penetrates the insulating layer 42 and is connected to an upper wiring ML. The upper wiring ML is connected to a transistor Tr formed on a substrate SB1 such as a silicon wafer through a via V. The upper wiring ML, the via V, the transistor Tr, and the like are covered with the insulating layer 50 such as silicon oxide and controls the memory cell as a peripheral circuit part PER. For convenience of description of FIG. 2Ba and subsequent drawings, part of the peripheral circuit part PER is not illustrated in some cases.

The platy member STL penetrates the first stacked body LM1, the second stacked body LM2, the insulating layers 31 to 33, and the insulating layers 41 and 42 in the z direction, and terminates in the source line SL. Specifically, the platy member STL includes a first platy member ST1 that extends in the x direction and penetrates the first stacked body LM1 and the insulating layers 31 to 33 in the z direction, and a second platy member ST2 that extends in the x direction, penetrates the second stacked body LM2 and the insulating layers 41 and 42 in the z direction, and is connected to an upper end of the first platy member ST1.

In the first platy member ST1, the conductive member EC including a conductive material and the liner layer LL are formed in order from the inside. In addition, even in the second platy member ST2, the conductive member EC and the liner layer LL are formed in order from the inside. An upper end of the conductive member EC in the second platy member ST2 is connected to a lower end of the conductive member EC in the first platy member ST1.

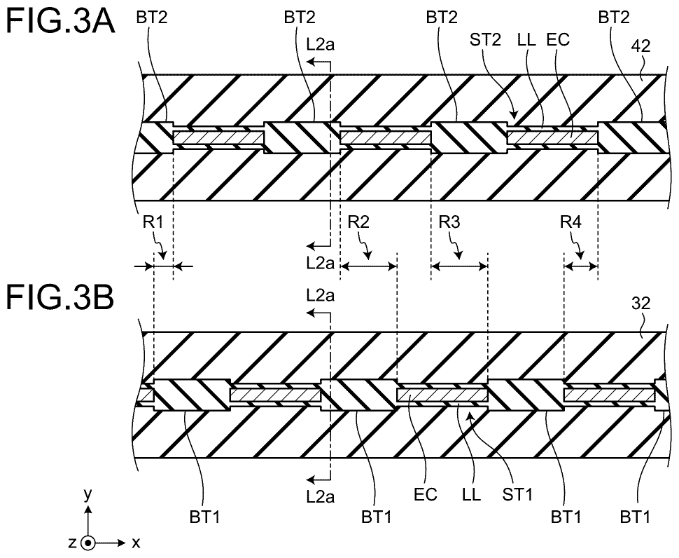

As illustrated in FIG. 2Ba, in part of upper ends of the first platy members ST1 and the second platy members ST2 extending in the x direction, a first bridging member BT1 and a second bridging member BT2 are formed. On the other hand, as illustrated in FIG. 2Bb, in the other part of the upper ends of the first platy members ST1 and the second platy members ST2 extending in the x direction, the first bridging member BT1 and the second bridging member BT2 are not formed. The reason for this is that the first bridging members BT1 and the second bridging members BT2 are intermittently disposed in the x direction. A specific positional relationship between the first bridging members BT1 and the second bridging members BT2 will be described below using FIGS. 3A and 3B.

The first bridging member BT1 includes an upper structure BTU1 that reaches a predetermined depth from an upper surface of a first interlayer insulating film 30, and a lower structure BTB1 that penetrates the first interlayer insulating film 30 from a predetermined depth of the first interlayer insulating film 30 and reaches a predetermined depth of the first platy member ST1. The lower structure BTB1 is positioned above the uppermost conductive layer WL1 in the first stacked body LM1. In addition, the width of the lower structure BTB1 in the y direction is substantially the same as the width of the first platy member ST1 in the y direction and is narrower than the width of the upper structure BTU1 in the y direction. The first bridging member BT1 is, for example, a silicon oxide layer.

In the upper structure BTU1 of the first bridging member BT1, a junction part BTO1 is formed. Even in the junction part BTO1, the conductive member EC including a conductive material and the liner layer LL are formed in order from the inside. The width of the conductive member EC of the junction part BTO1 in the y direction is wider than at least the width of the lower end of the second platy member ST2 in the y direction, and is connected to the lower end of the conductive member EC in the second platy member ST2. The width of the conductive member EC of the junction part BTO1 in the y direction may be wider than the width of the conductive member EC of the first platy member ST1 in the y direction.

The second bridging member BT2 includes an upper structure BTU2 that reaches a predetermined depth from an upper surface of the second interlayer insulating film 40, and a lower structure BTB2 that penetrates the second interlayer insulating film 40 from a predetermined depth of the second interlayer insulating film 40 and reaches a predetermined depth of the second platy member ST2. The lower structure BTB2 is positioned above the uppermost conductive layer WL2 in the second stacked body LM2, namely, above the drain-side select gate line SGD. In addition, the width of the lower structure BTB2 in the y direction is substantially the same as the width of the second platy member ST2 in the y direction and is narrower than the width of the upper structure BTU2 in the y direction. The second bridging member BT2 is, for example, a silicon oxide layer.

As illustrated in FIGS. 2Ba and 2Bb, in the staircase region SA, a first staircase part SR1, a second staircase part SR2, a contact CC, and a pillar-like member HR are formed.

The first staircase part SR1 and the second staircase part SR2 are formed by processing the first stacked body LM1 and the second stacked body LM2 in a staircase shape, respectively. Specifically, as illustrated in FIG. 2Ba, the first staircase part SR1 is included in the first stacked body LM1, and is processed in a staircase shape that the conductive layers WL1 extend in the x direction. In addition, as illustrated in FIG. 2Bb, the second staircase part SR2 is included in the second stacked body LM2, and is processed in a staircase shape that the conductive layers WL2 are continuous to the first staircase part SR1 in the x direction.

FIG. 2Ba illustrates the lowermost step of the first staircase part SR1, namely, a part where the lowermost conductive layer WL1 in the first stacked body LM1 is processed in a staircase shape. Thus, in FIG. 2Ba, the first staircase part SR1 extends to the front side in the paper plane. In addition, a dummy staircase part is formed on both sides in the y direction of the first staircase part SR1 extending in the x direction. These dummy staircase parts are configured to be formed during the formation of the first staircase part SR1, and do not have a function of electrically leading out each of the conductive layers WL1 unlike the normal first staircase part SR1.

In addition, FIG. 2Bb illustrates the lowermost step of the second staircase part SR2, namely, a part where the lowermost conductive layer WL2 in the second stacked body LM2 is processed in a staircase shape. Thus, in FIG. 2Bb, the second staircase part SR2 also extends to the front side in the paper plane. In addition, a dummy staircase part that does not have a function as the normal second staircase part SR2 is formed on both sides in the y direction of the second staircase part SR2 extending in the x direction.

At a height position of the first stacked body LM1, the first staircase part SR1 is covered with an insulating layer 34, and the insulating layers 31 to 33 are formed on the insulating layer 34. The insulating layer 34 is, for example, a silicon oxide layer. Accordingly, the insulating layers 31 to 34 are substantially integrated. In the following description, the insulating layers 31, 32, and 34 among the insulating layers 31 to 34 will also be referred to as the first interlayer insulating film 30. In addition, at a height position of the second stacked body LM2, the second staircase part SR2 is covered with an insulating layer 43, and the insulating layers 41 and 42 are formed on the insulating layer 43. The insulating layer 43 is, for example, a silicon oxide layer. Accordingly, the insulating layers 41 to 43 are substantially integrated. In the following description, the insulating layers 41 to 43 will also be referred to as the second interlayer insulating film 40.

Part of the contacts CC penetrates the first interlayer insulating film 30 and the second interlayer insulating film 40 and are connected to the conductive layers WL1 configuring the respective steps of the first staircase part SR1. The other part of the contacts CC penetrates the second interlayer insulating film 40 and is connected to the conductive layers WL2 configuring the respective steps of the second staircase part SR2. FIGS. 2Ba and 2Bb illustrate the contact CC connected to the lowermost steps of the first staircase part SR1 and the second staircase part SR2, respectively. The contacts CC are connected to the upper wirings not illustrated in FIGS. 2Ba and 2Bb. As a result, each of the conductive layers WL1 and WL2 is electrically led out.

The pillar-like member HR penetrates the first stacked body LM1, insulating layers 31 to 33, the second stacked body LM2, and the insulating layer 41 in the z direction and terminates in the source line SL. In the present embodiment, a hole of the pillar-like member HR is filled with the same material as the core layer COR, the channel layer CHN, the memory film MEM, and the cap layer CAP, and the pillar-like member HR has the same layer structure as that of the memory pillar MP. However, the pillar-like member HR does not contribute to the function of the semiconductor memory device 1. When the first stacked body LM1 and the second stacked body LM2 are formed from a stacked body (described below) in which sacrificial layers and insulating layers are stacked, the pillar-like member HR supports these configurations.

FIGS. 3A and 3B are diagrams illustrating a positional relationship between the first bridging member BT1 and the second bridging member BT2 according to the first embodiment. FIG. 3A is an xy cross-sectional view taken along line L3-L3 of FIG. 2Ba, and FIG. 3B is an xy cross-sectional view taken along line L4-L4 of FIG. 2Ba. Thus, FIGS. 3A and 3B are top views in an extending direction of the first platy member ST1 and the second platy member ST2. In addition, for example, as in the line L2a-L2a illustrated in FIG. 1, the yz cross-section taken along the line L2a-L2a illustrated in FIGS. 3A and 3B corresponds to the surface illustrated in FIG. 2Ba.

As illustrated in FIGS. 3A and 3B, the first bridging members BT1 and the second bridging members BT2 are intermittently provided in the upper ends of the first platy member ST1 and the second platy member ST2 extending in the x direction, respectively. The first bridging member BT1 and the second bridging member BT2 are formed to stride over the first platy member ST1 and the second platy member ST2 in the y direction, respectively. In addition, when seen from the z direction, the first bridging member BT1 and the second bridging member BT2 are disposed to be shifted from each other in the x direction.

Specifically, when the position in the x direction is a position R1 in FIGS. 3A and 3B, the first bridging member BT1 and the second bridging member BT2 are disposed to overlap with each other. In addition, when the position in the x direction is a position R4, both the first bridging member BT1 and the second bridging member BT2 are not disposed. At the position R4, the shapes of the first platy member ST1 and the second platy member ST2 are shapes that the first bridging member BT1 and the second bridging member BT2 are not provided on the upper ends thereof, respectively, as illustrated in FIG. 2A. In addition, at a position R2 and a position R3, any one of the first bridging member BT1 or the second bridging member BT2 is disposed in either the first platy member ST1 or the second platy member ST2, but the first bridging member BT1 and the second bridging member BT2 do not overlap with each other when seen from the z direction.

The positional relationship between the first bridging member BT1 and the second bridging member BT2 illustrated in FIGS. 3A and 3B are merely exemplary, and the present embodiment is not limited thereto. The positional relationship between the first bridging member BT1 and the second bridging member BT2, the lengths thereof in the x direction, the intervals thereof adjacent to each other, the numbers thereof, and the like may be appropriately determined.

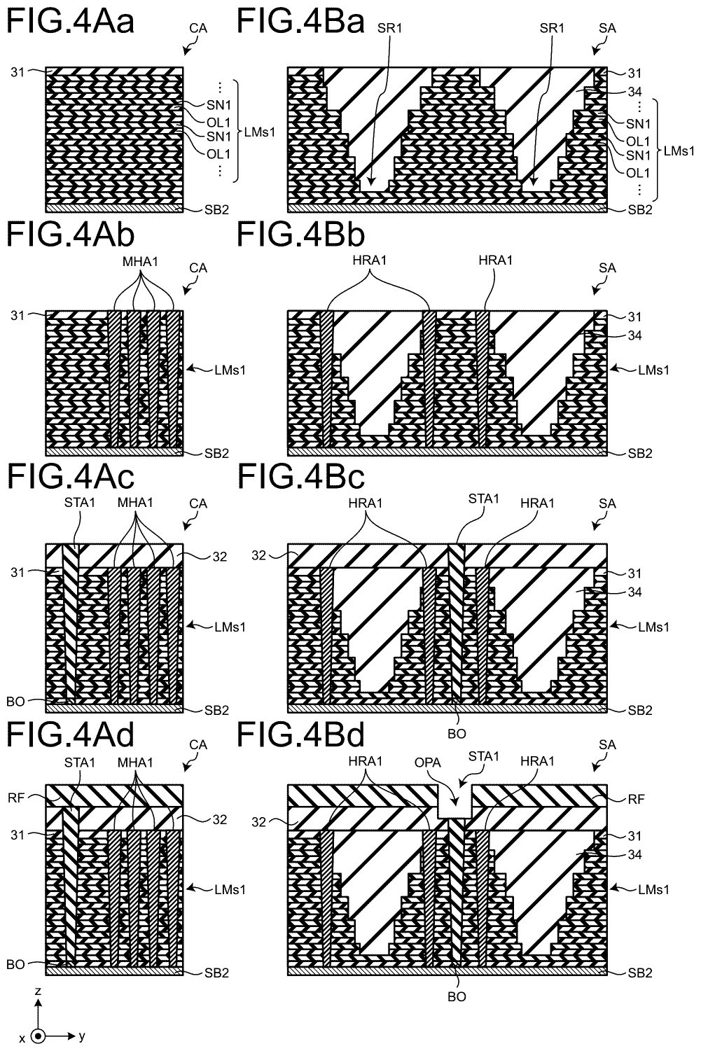

Hereinafter, a method of forming each of the configurations in the cell array region CA and the staircase region SA according to the first embodiment will be described with reference to FIGS. 4Aa to 10Bp. FIGS. 4Aa to 10Bp are diagrams illustrating part of a procedure of the method of manufacturing the semiconductor memory device 1 according to the first embodiment. FIGS. 4Aa to 10Ap are yz cross-sectional views taken along the line L1-L1 of FIG. 1, and correspond to the cross-section illustrated in FIG. 2A. FIGS. 4Ba to 10Bp are yz cross-sectional views taken along the line L2a-L2a of FIG. 1, and correspond to the cross-section illustrated in FIG. 2Ba.

In FIGS. 4Aa and 4Ba, a first stacked body LMs1 and the insulating layer 31 are formed in this order on a substrate SB2 such as a silicon wafer. The first stacked body LMs1 is formed by alternately stacking insulating layers OL1 and sacrificial layers SN1 one by one. As illustrated in FIG. 4Ba, part of the first stacked body LMs1 and the insulating layer 31 is processed into the first staircase part SR1 through a series of steps including forming a mask using photoresist, etching using this mask, slimming of the mask, and etching using the slimmed mask. The first staircase part SR1 is formed in a staircase shape that the sacrificial layers SN1 extend in the x direction. At this time, the mask is slimmed not only in the x direction but also in the y direction. Therefore, the dummy staircase part is formed on both sides of the first staircase part SR1 in the y direction. Next, the first staircase part SR1 is covered with the insulating layer 34.

The insulating layer OL1 is an example of the first insulating layer, and the sacrificial layer SN1 is an example of the second insulating layer. The insulating layer OL1 is, for example, a silicon oxide layer, and the sacrificial layers SN1 is, for example, a silicon nitride layer.

In FIGS. 4Ab and 4Bb, a memory hole MHA1 and a hole HRA1 that penetrate the first stacked body LMs1, the insulating layer 31, and the insulating layer 34 are formed. The memory hole MHA1 and the hole HRA1 are provided to form the memory pillar MP and the pillar-like member HR, respectively. Next, the memory hole MHA1 and the hole HRA1 are embedded with amorphous carbon. At this time, the amorphous carbon deposited on the insulating layer 31 and the insulating layer 34 is removed by, for example, chemical mechanical polishing (CMP).

In FIGS. 4Ac and 4Bc, the insulating layer 32 is formed on the insulating layer 31 and the insulating layer 34. In this way, the first staircase part SR1 is covered with the first interlayer insulating film 30. Next, a slit STA1 that penetrates the first stacked body LMs1 and the first interlayer insulating film 30 and terminates in the substrate SB2 is formed. The slit STA1 is an example of the first groove and is configured to be the first platy member ST1 subsequently. Accordingly, the slit STA1 also extends in a direction along the x direction.

Next, an oxide layer BO is formed in a bottom part of the slit STA1. Next, the slit STA1 is embedded with amorphous silicon. As a result, the oxide layer BO can function as an etching stopper when the amorphous silicon is subsequently removed from the slit STA1.

Next, in a region where the first bridging member BT1 and the second bridging member BT2 are subsequently disposed as in the cross-section of FIG. 4Bd, a photoresist film RF is applied to the insulating layer 32, and the photoresist film RF is opened by light exposure and development such that the upper side of the slit STA1 is exposed. By using the photoresist film RF as a mask, the insulating layer 32 is dry-etched up to a depth preventing the insulating layer 32 from not being penetrated. As a result, an opening part OPA is formed in an upper end of the slit STA1. The opening part OPA is a part for subsequently forming the upper structure BTU1 of the first bridging member BT1.

As described above, the photoresist film RF is opened such that the width of the opening part OPA in the y direction is wider than the width of the slit STA1 in the y direction. As a result, a wide allowable range of displacement of the opening part of the photoresist film RF relative to the slit STA1 can be ensured, and the first bridging member BT1 can be more reliably formed in the upper end of the first platy member ST1.

On the other hand, in a region where the first bridging member BT1 and the second bridging member BT2 are not subsequently disposed as in the cross-section of FIG. 4Ad, the opening part is not formed in the photoresist film RF, and thus the opening part OPA is not formed.

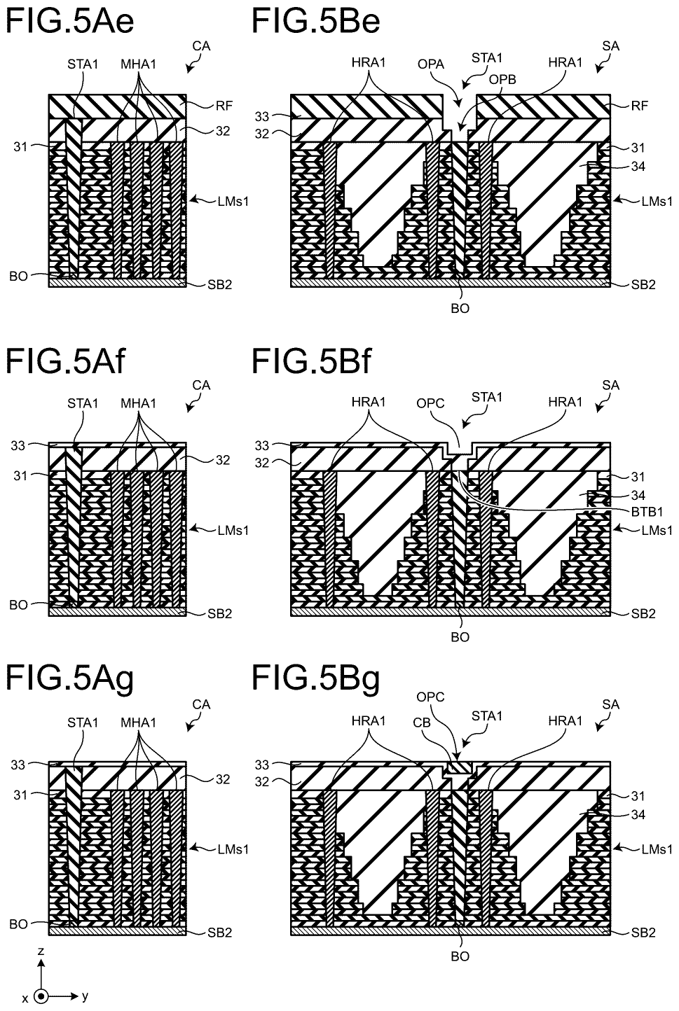

Next, in a region where the first bridging member BT1 and the second bridging member BT2 are subsequently disposed as in the cross-section of FIG. 5Be, the amorphous silicon exposed from the bottom part of the opening part OPA after the formation of the opening part OPA is dry-etched up to a predetermined depth by gas different from etching gas for processing the opening part OPA. The predetermined depth is a depth above the uppermost sacrificial layer SN1 of the first stacked body LMs1. As a result, an opening part OPB is formed in the bottom part of the opening part OPA. The opening part OPB is a part for subsequently forming the lower structure BTB1 of the first bridging member BT1. On the other hand, in a region where the first bridging member BT1 and the second bridging member BT2 are not subsequently disposed as in the cross-section of FIG. 5Ae, the opening part OPB is not formed.

In FIG. 5Bf, after removing the photoresist film RF, the insulating layer 33 is deposited on the insulating layer 32. The insulating layer 33 is deposited on the bottom surfaces and side walls of the opening parts OPA and OPB. When the insulating layer 33 is deposited on each of the above-described parts and reaches a predetermined film thickness, the opening part OPB is substantially completely filled with the insulating layer 33, and the lower structure BTB1 of the first bridging member BT1 is formed.

In addition, an opening part OPC is formed inside the opening part OPA covered with the insulating layer 33. At this time, the insulating layer 33 is formed such that a state where the width of the opening part OPC in the y direction is wider than the width of a lower end of a slit STA2 that is subsequently formed in the y direction is maintained. As a result, a wide allowable range of displacement of the slit STA2 that is subsequently formed relative to the opening part OPC can be ensured.

On the other hand, in FIG. 5Af, the insulating layer 33 is merely deposited on the insulating layer 32.

In FIG. 5Bg, the opening part OPC is filled with an amorphous carbon layer CB. The amorphous carbon layer CB functions as an etching stopper when the second platy member ST2 is subsequently processed. On the other hand, in FIG. 5Ag, the amorphous carbon layer CB is not formed.

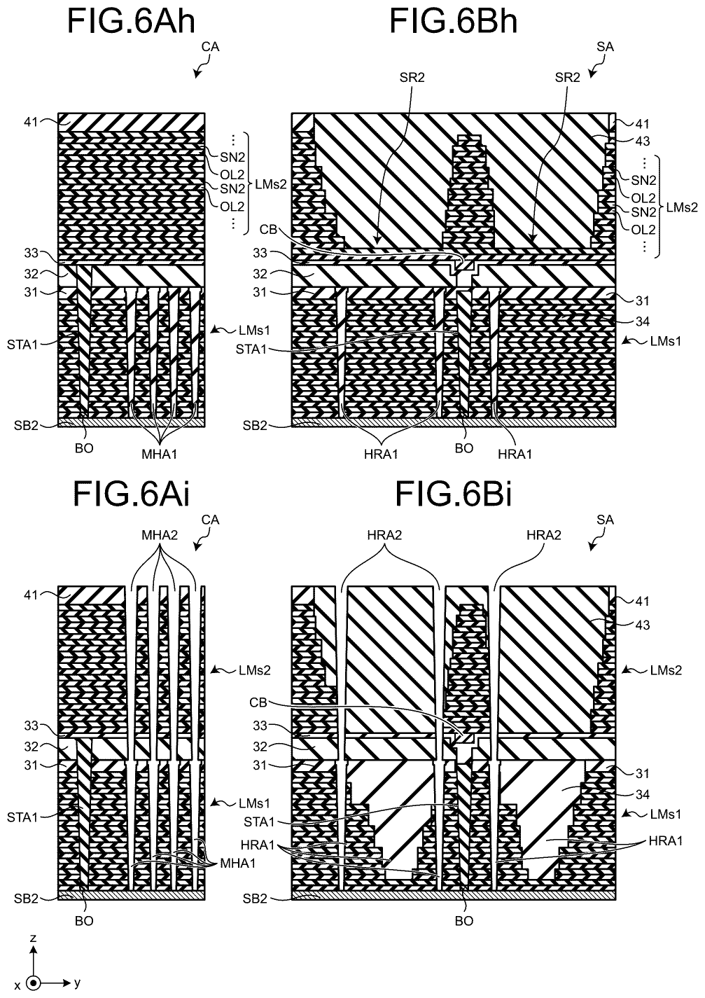

Hereinafter, FIG. 6Bh illustrates a state where a second stacked body LMs2 and the second staircase part SR2 are formed. In order to illustrate the second staircase part SR2, FIG. 6Bh illustrates a cross-section different from those of FIGS. 4Ba to 10Bp.

As illustrated in FIG. 6Bh, the second stacked body LMs2 and the insulating layer 41 are formed in this order on the insulating layer 33. The second stacked body LMs2 is formed by alternately stacking insulating layers OL2 and sacrificial layers SN2 one by one. Part of the second stacked body LMs2 and the insulating layer 41 is processed into the second staircase part SR2 by, for example, the same step as that of the first staircase part SR1. The second staircase part SR2 is processed in a staircase shape that the sacrificial layers SN2 are continuous to the first staircase part SR1 in the x direction.

FIG. 6Bh illustrates the lowermost step of the second staircase part, namely, a part where the lowermost sacrificial layer SN2 in the second stacked body LMs2 is processed in a staircase shape. Even when the second staircase part SR2 is formed, a dummy staircase part is formed on both sides of the second staircase part SR2 in the y direction as in the formation of the first staircase part SR1.

Next, the second staircase part SR2 is covered with the insulating layer 43.

The insulating layer OL2 is an example of the third insulating layer, and the sacrificial layer SN2 is an example of the fourth insulating layer. The insulating layer OL2 is, for example, a silicon oxide layer, and the sacrificial layers SN2 is, for example, a silicon nitride layer.

In FIGS. 6Ai and 6Bi, a memory hole MHA2 and a hole HRA2 that penetrate the second stacked body LMs2, the insulating layer 41, and the insulating layer 43 are formed. The memory hole MHA2 and the hole HRA2 are connected to upper ends of the memory hole MHA1 and the hole HRA1 formed in the first stacked body LMs1, respectively. Next, the amorphous carbon embedded in the memory hole MHA1 and the hole HRA1 is removed by ashing treatment or the like through the memory hole MHA2 and the hole HRA2.

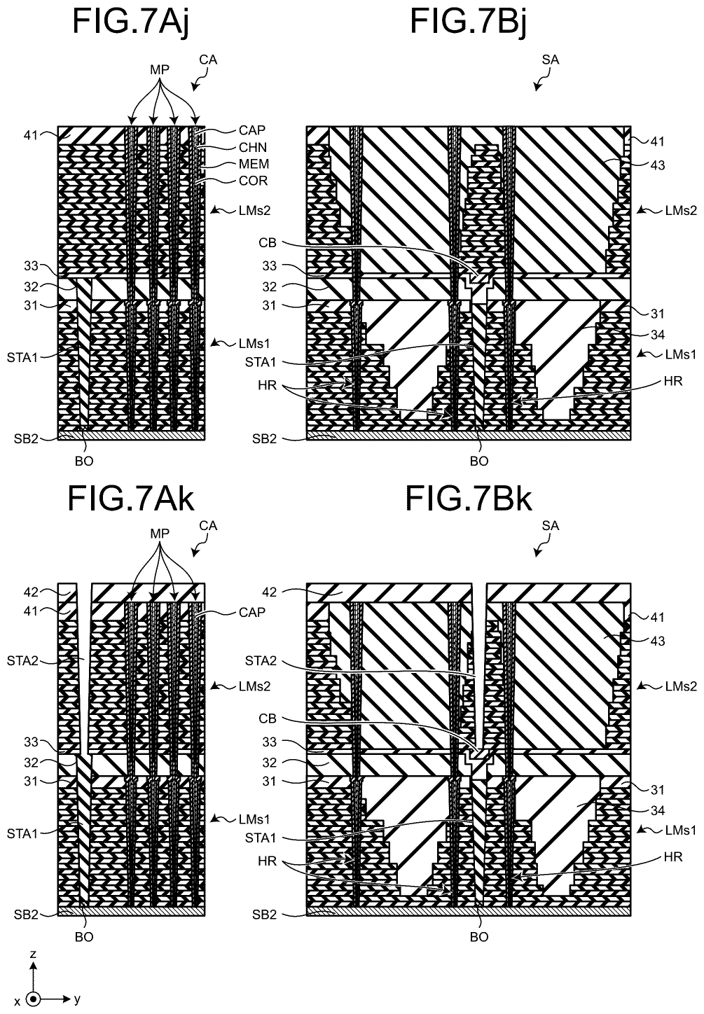

In FIGS. 7Aj and 7Bj, the memory film MEM, the channel layer CHN, and the core layer COR are formed in this order inside the memory holes MHA1 and MHA2. Next, the core layer COR is retreated by dry-etching and the cap layer CAP is embedded. As a result, the memory pillar MP is formed. In addition, concurrently with the formation of the memory pillar MP, the same process is performed on the holes HRA1 and HRA2, and the pillar-like member HR is formed.

In FIGS. 7Ak and 7Bk, the insulating layer 42 is formed on the insulating layers 41 and 43 that cover the first stacked body LMs1 and the second stacked body LMs2 in which the memory pillar MP and the pillar-like member HR are formed. In this way, the second staircase part SR2 is covered with the second interlayer insulating film 40. Next, the slit STA2 that has an opening at a position overlapping with the slit STA1 formed in the first stacked body LMs1 in the z direction and penetrates the second stacked body LMs2 and the second interlayer insulating film 40 is formed. The slit STA2 is provided to form the second platy member ST2. In addition, the slit STA2 is an example of the second groove.

In a region where the first bridging member BT1 and the second bridging member BT2 are not subsequently disposed as in the cross-section of FIG. 7Ak, the slit STA2 extends in the x direction, penetrates the insulating layer 33 covering the slit STA1, and is connected to the upper end of the slit STA1.

Specifically, as illustrated in FIG. 7Ak, in a place where the lower structure BTB1 of the first bridging member BT1 and the opening part OPC filled with the amorphous carbon layer CB are not formed in the upper end of the slit STA1, the slit STA2 is directly connected to an upper end opening part of the slit STA1. On the other hand, as illustrated in FIG. 7Bk, in a place where the lower structure BTB1 of the first bridging member BT1 and the opening part OPC filled with the amorphous carbon layer CB are formed in the upper end of the slit STA1, the slit STA2 is connected to the amorphous carbon layer CB formed in the opening part OPC.

At this time, as in the above-described insulating layer 33, etching conditions of the slit STA2 do not have selectivity to the silicon oxide layer or the like forming the lower structure BTB1 of the first bridging member BT1 provided on the upper end of the slit STA1. By providing the amorphous carbon layer CB above the lower structure BTB1, the etching of the slit STA2 can be stopped on the amorphous carbon layer CB, and the penetration of the lower end of the slit STA2 into the lower structure BTB1 is suppressed. As a result, a function of the first bridging member BT1 that is subsequently formed is maintained, the function connecting the first interlayer insulating films 30 on both sides in the y direction to each other above the first platy member ST1 that is subsequently formed.

In addition, as described above, the amorphous carbon layer CB is formed to be wider than the width of the lower end of the slit STA2 in the y direction. As a result, a wide allowable range of displacement of the slit STA2 relative to the amorphous carbon layer CB can be ensured, and the lower end of the slit STA2 can be made to more reliably reach the inside the plane of the amorphous carbon layer CB. Accordingly, the etching of the lower end of the slit STA2 can be more reliably stopped by the amorphous carbon layer CB.

Although not illustrated in FIG. 7Bk, the amorphous carbon layer CB is removed by ashing treatment or the like after formation of the slit STA2. In the part where the amorphous carbon layer CB is removed, the opening part OPC is exposed again.

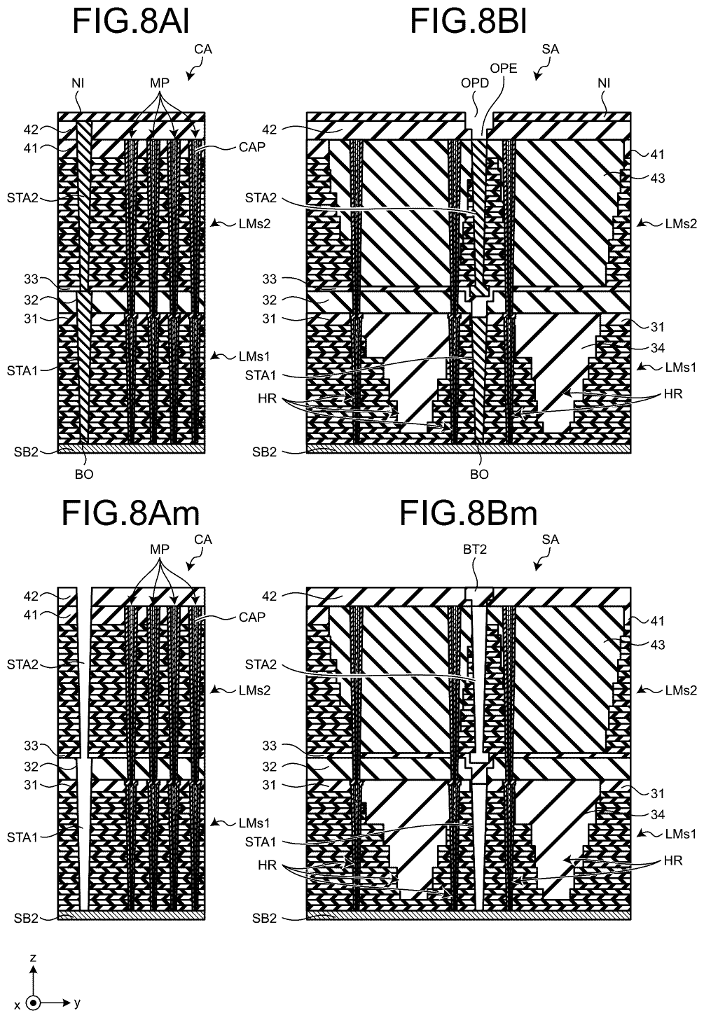

Next, as illustrated in FIGS. 8A1 and 8B1, the slit STA2 and the opening part OPC are filled with amorphous silicon, and a silicon nitride layer NI is deposited on the insulating layer 42. Next, in a region where the first bridging member BT1 and the second bridging member BT2 are subsequently disposed as in the cross-section of FIG. 8B1, by performing a process corresponding to the process of FIGS. 4Bd and 5Be on the silicon nitride layer NI, an opening part OPD where the width in the y direction is wider than the slit STA2 is formed on the silicon nitride layer NI above the slit STA2. Further, an opening part OPE where the width in the y direction is substantially the same as that of the slit STA2 and that reaches a predetermined depth of the slit STA2 is formed. The opening part OPE is formed at a depth above the uppermost sacrificial layer SN2 of the second stacked body LMs2. In addition, the silicon nitride layer NI functions as a CMP stopper when the second bridging member BT2 is formed in the opening part OPD. On the other hand, in a region where the first bridging member BT1 and the second bridging member BT2 are not subsequently disposed as in the cross-section of FIG. 8A1, the opening parts OPD and OPE are not formed.

In FIG. 8Bm, the opening parts OPD and OPE are embedded with silicon oxide. The silicon oxide deposited on the silicon nitride layer NI is removed by CMP, for example. As a result, the second bridging member BT2 is formed in the opening parts OPD and OPE. In this way, the second bridging member BT2 connects the second interlayer insulating films 40 on both sides of the slit STA1. In addition, as described above, a lower end of the opening part OPE is positioned above the uppermost sacrificial layer SN2 of the second stacked body LMs2. Accordingly, the lower end of the second bridging member BT2 is also positioned above the uppermost sacrificial layer SN2.

Next, when the silicon nitride layer NI is removed by dry-etching or the like, as illustrated in FIG. 8Am, a part of an upper end of the slit STA2 where the second bridging member BT2 is not formed is opened. Next, the amorphous silicon filled in the slit STA1, the opening part OPC, and the slit STA2 is removed by wet-etching. A process liquid enters into an upper end opening of the slit STA2 (part where the second bridging member BT2 is not formed), and reaches the opening part OPC from below the second bridging member BT2 is diffused up to a lower end of the slit STA1 through the upper end opening of the slit STA1 (part where the lower structure BTB1 of the first bridging member BT1 and the opening part OPC filled with amorphous silicon are not formed). As a result, the amorphous silicon is removed from the slit STA1, the opening part OPC, and the slit STA2.

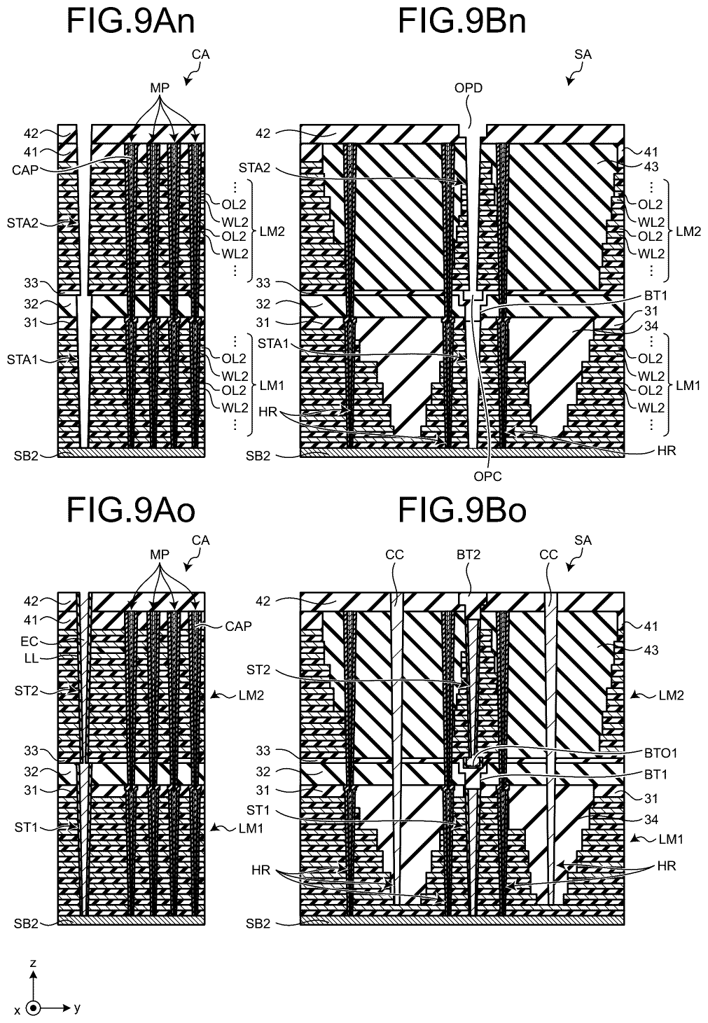

Next, as illustrated in FIGS. 9An and 9Bn, in the parts of the first stacked body LMs1 and the second stacked body LMs2 where the sacrificial layers SN1 and SN2 are present, the conductive layers WL1 and WL2 are formed to form the first stacked body LM1 and the second stacked body LM2. Specifically, the sacrificial layers SN1 and SN2 are removed by wet-etching. As described above, the process liquid enters into the upper end opening of the slit STA2 and is diffused up to the lower end through the opening part OPC and the upper end opening of the slit STA1. As a result, the sacrificial layers SN1 and SN2 exposed to side surfaces of the slits STA1 and STA2 are removed in the x direction and the y direction, and a space (not illustrated) that extends on an xy plane and is disposed in a layer shape in the z direction is formed between the insulating layers OL1 and OL2.

Next, when a metal layer such as tungsten or molybdenum is embedded in the space after forming an insulating layer such as aluminum oxide in the space through the slits STA1 and STA2 by, for example, atomic layer deposition (ALD), the conductive layers WL1 and WL2 are obtained. Thus, the sacrificial layers SN1 and SN2 are replaced with the conductive layers WL1 and WL2 to form the first stacked body LM1 and the second stacked body LM2. Next, the metal layer remaining in the side wall parts of the slits STA1 and STA2 is removed by the wet-etching process. The process of replacing the sacrificial layers SN1 and SN2 with the conductive layers WL1 and WL2 will also be referred to as a replacement process.

In FIGS. 9Ao and 9Bo, the liner layer LL and the conductive member EC are formed in this order inside the slits STA1 and STA2. As in the above-described process liquid, raw material gas of each of the liner layer LL and the conductive member EC enters into the upper end opening of the slit STA2, and reaches the opening part OPC or is diffused up to the lower end of the slit STA1 through the upper end opening of the slit STA1. As a result, the first platy member ST1 and the second platy member ST2 are formed. In addition, the junction part BTO1 is formed in the opening part OPC, and the first bridging member BT1 including the junction part BTO1 is formed in the upper end of the slit STA1. In addition, here, the contacts CC that the conductive layers WL1 and WL2 reach, respectively, may be formed.

The first bridging member BT1 connects the first interlayer insulating films 30 on both sides of the slit STA1.

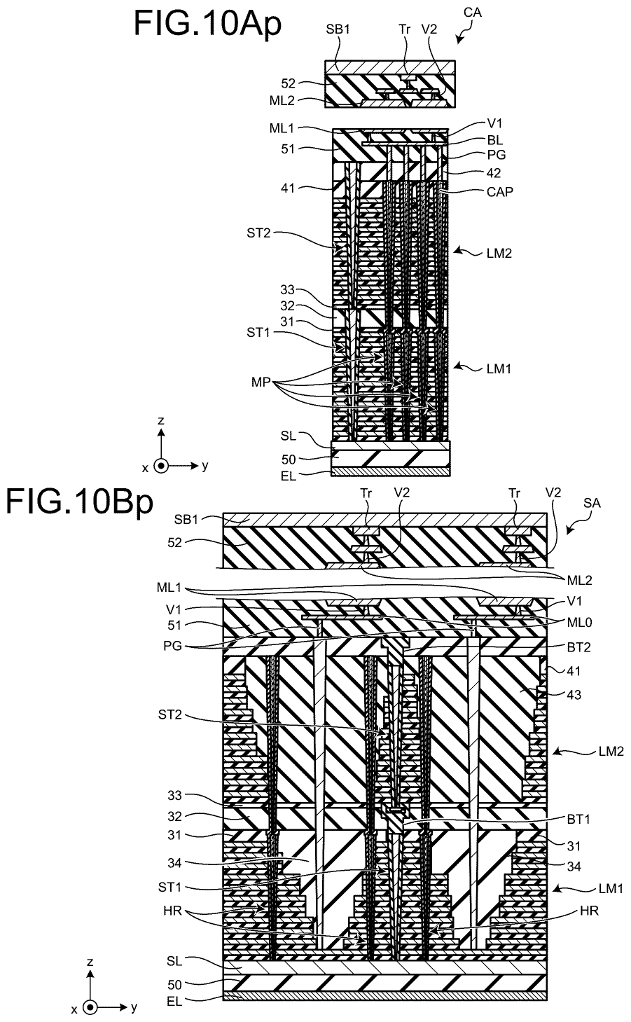

In FIGS. 10Ap and 10Bp, the plug PG, a bit line BL, an upper wiring MLO, a via V1, and an upper wiring ML1 that are connected to the memory pillar MP or the contact CC are formed on an upper surface of the insulating layer 42, and are covered with an insulating layer 51. The upper wiring ML1 is exposed to the surface of the insulating layer 51. On the other hand, the transistor Tr, a via V2, and an upper wiring ML2 are formed on a substrate SB1 different from the substrate SB2, and are covered with an insulating layer 52. The upper wiring ML2 is exposed to the surface of the insulating layer 52. The substrate SB1 and the substrate SB2 are bonded to each other such that the upper wiring ML1 and the upper wiring ML2 vertically overlap with each other. The insulating layers 51 and 52 are, for example, silicon oxide layers and are substantially integrated.

Next, the substrate SB2 is polished from below the first stacked body LM1, the memory pillar MP, the pillar-like member HR, and the lower end of the first platy member ST1 are exposed, and the source line SL, the insulating layer 50, and the electrode film EL are formed in this order on the exposed surface. As a result, the conductive members EC formed in the first platy member ST1 and the second platy member ST2 are connected to the source line SL. In addition, the channel layer CHN of the memory pillar MP and the source line SL are connected to each other. As a result, the semiconductor memory device 1 is manufactured.

### COMPARATIVE EXAMPLE

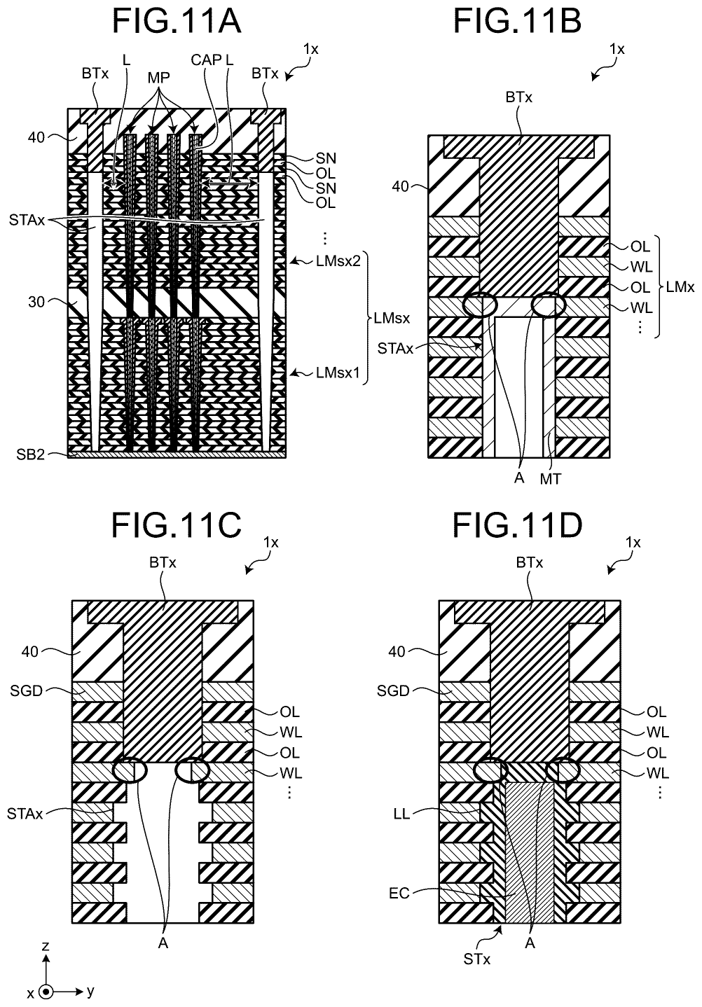

FIGS. 11A to 11D are cross-sectional views illustrating a detailed configuration of a cell array region of a semiconductor memory device 1x according to Comparative Example. The semiconductor memory device 1x according to Comparative Example is different from the semiconductor memory device 1 according to the first embodiment in the number of the bridging members disposed and the disposition positions of the bridging members. FIG. 11A is a diagram illustrating a state of a stacked body LMsx before the replacement process. FIGS. 11B and 11C are diagrams illustrating a state of a stacked body LMx during the replacement process. FIG. 11D is a diagram illustrating a state of the stacked body LMx after the replacement process.

As illustrated in FIG. 11A, when distances L of the memory pillar MP from the slit STAx in the y direction on both sides in the y direction of the slit STAx that extends in the cell array region in the x direction are different from each other, there may be a difference in the contraction stress of the stacked body LMsx divided by the slit STAx on both sides of the slit STAx in the y direction. In addition, a staircase part (not illustrated) is covered with a thick interlayer insulating film, and there may be a different in expansion stress and contraction stress between the thick interlayer insulating film and the stacked body having a stacked structure of different layers.

As a result, deflection or inclination may occur in the stacked body LMsx and the memory pillars, the pillar-like members, or the like provided in the stacked body LMsx. When deflection or inclination occurs in the stacked body LMsx, the stacked body LMsx may collapse, and a space between the insulating layers OL may be blocked such that formation failure of the conductive layers WL occurs. When deflection or inclination occurs in the memory pillars, the pillar-like members, or the like, the memory pillar, the pillar, or the like may come into contact with the contact formed in the slit STAx or the staircase part.

Accordingly, in order to reduce the deflection and the inclination, a bridging member BTx that connects the interlayer insulating films on both sides of the slit STAx in the y direction may be formed above the slit STAx. As a result, a difference in stress between both sides of the slit STAx in the y direction can be alleviated through the bridging member BTx.

Recently, as the storage capacity of the semiconductor memory device increases, the number of layers stacked in the stacked body LMx increases. As the number of layers stacked in the stacked body LMx increases, the stress generated in the layers increases, and thus thickening of the bridging member BTx is required. However, when the film thickness of the bridging member BTx increases, the bridging member BTx may be formed up to a depth facing the sacrificial layer SN of the stacked body LMsx.

Note that, during the replacement process, the raw material gas of the conductive layer WL is likely to be accumulated at a position immediately below the bridging member BTx, and a thick metal layer MT may be formed on a lower surface of the bridging member BTx in the slit STAx. As illustrated in FIG. 11B, when the bridging member BTx may be formed up to a depth facing the sacrificial layer SN of the stacked body LMsx, the metal layer MT is formed locally thick on an exposed surface A that is exposed in the slit STAx of the conductive layer WL formed at the position immediately below the bridging member BTx.

As illustrated in FIG. 11C, the metal layer MT that is formed thick on the exposed surface A may remain immediately below the bridging member BTx even after the metal layer is removed from the side wall parts of the slit STAx after the end of the replacement process. As a result, as illustrated in FIG. 11D, a conductive member EC of a platy member STx that subsequently functions as a source line contact and the metal layer MT that is added to the exposed surface A of the conductive layer WL are adjacent to each other such that the voltage resistance performance may decrease. On the other hand, when an excessive process is performed to remove the metal layer MT, the metal layer of the conductive layer WL may be dissolved more than necessary.

The semiconductor memory device 1 according to the first embodiment includes the first bridging member BT1 and the second bridging member BT2. The first bridging member BT1 is provided on the upper end of the first platy member ST1. The first bridging member BT1 connects the first interlayer insulating films 30 on both sides of the first platy member ST1. The second bridging member BT2 is provided on the upper end of the second platy member ST2. The second bridging member BT2 connects the second interlayer insulating films 40 on both sides of the second platy member ST2.

In this way, by providing the first bridging member BT1 and the second bridging member BT2 in the first platy member ST1 and the second platy member ST2, respectively, as compared to for example, a case where only the bridging member is provided on the upper end of the second platy member ST2, the first interlayer insulating films 30 and the second interlayer insulating films 40 can be strongly connected on both sides of the first platy member ST1 and both sides of the second platy member ST2, respectively. Therefore, deflection and inclination of the first stacked body LM1 and the second stacked body LM2 are reduced.

In the semiconductor memory device 1 according to the first embodiment, the lower ends of the first bridging member BT1 and the second bridging member BT2 are positioned above the uppermost conductive layers WL1 and WL2 in the first stacked body LM1 and the second stacked body LM2, respectively.

As described above, the first bridging member BT1 and the second bridging member BT2 corresponding to the first stacked body LM1 and the second stacked body LM2, respectively, are provided. Therefore, the first bridging member BT1 and the second bridging member BT2 can be formed thin. As a result, the addition of the metal layer MT that is formed thick immediately below the first bridging member BT1 and the second bridging member BT2 to the exposed surfaces of the conductive layers WL1 and WL2 immediately below the first bridging member BT1 and the second bridging member BT2 can be suppressed. As a result, a decrease in voltage resistance performance between the conductive layers WL1 and WL2 and the first and second platy members ST1 and ST2 can be suppressed.

In the semiconductor memory device 1 according to the first embodiment, the first bridging member BT1 includes: the upper structure BTU1 where the width in the y direction is wider than the width of the first platy member ST1 in the y direction; and the lower structure BTB1 where the width in the y direction is narrower than the width of the upper structure BTU1 in the y direction and that connects the upper structure BTU1 and the first platy member ST1.

In this way, since the first bridging member BT1 has the upper structure BTU1, when the first bridging member BT1 is formed, a wide allowable range of displacement of the first bridging member BT1 relative to the first platy member ST1 can be ensured. Accordingly, the first interlayer insulating films 30 on both sides of the first platy member ST1 in the y direction can be more reliably connected by the first bridging member BT1.

In the semiconductor memory device 1 according to the first embodiment, the junction part BTO1 in the upper structure BTU1 of the first bridging member BT1 includes the conductive member EC where the width in the y direction is wider than the width of the lower end of the second platy member ST2 in the y direction.

As described above, when the slit STA2 for subsequently forming the second platy member ST2 is formed, the conductive member EC of the junction part BTO1 is filled with the amorphous carbon layer CB that functions as the etching stopper during the processing of the slit STA2. By forming the width of the amorphous carbon layer CB in the y direction to be wider than the width of the lower end of the slit STA2 in the y direction, a wide allowable range of displacement between the slit STA2 and the amorphous carbon layer CB can be ensured, and the etching of the slit STA2 can be more reliably stopped on the amorphous carbon layer CB.

In the above-described first embodiment, the first bridging member BT1 and the second bridging member BT2 are disposed to be shifted from each other in the x direction when seen from the z direction. More specifically, at a predetermined position in the x direction, the first bridging member BT1 and the second bridging member BT2 are disposed such that the part where the first bridging member BT1 and the second bridging member BT2 are disposed, the part where both the first bridging member BT1 and the second bridging member BT2 are not disposed, and the part where any of the first bridging member BT1 and the second bridging member BT2 is disposed are provided.

However, the disposition example of the first bridging member BT1 and the second bridging member BT2 shifted from each other in the x direction is not limited to the above-described example. By disposing the end of the first bridging member BT1 and the end of the second bridging member BT2 to overlap with each other when seen from the z direction, the first bridging member BT1 and the second bridging member BT2 may be disposed such that the part where both of the first bridging member BT1 and the second bridging member BT2 are not disposed is not provided. In addition, the first bridging member BT1 and the second bridging member BT2 may be disposed such that the part where the first bridging member BT1 and the second bridging member BT2 overlap with each other in the z direction is not provided at any position in the x direction.

Alternatively, the first bridging member BT1 and the second bridging member BT2 may be disposed to overlap with each other in the z direction, namely, not to be shifted from each other in the x direction. In this way, by freely determining the disposition of the first bridging member BT1 and the second bridging member BT2, the bridging strength of each of the first bridging member BT1 and the second bridging member BT2 can be appropriately adjusted, and deflection and inclination of the first stacked body LM1 and the second stacked body LM2 can be further suppressed.

### Modification Example

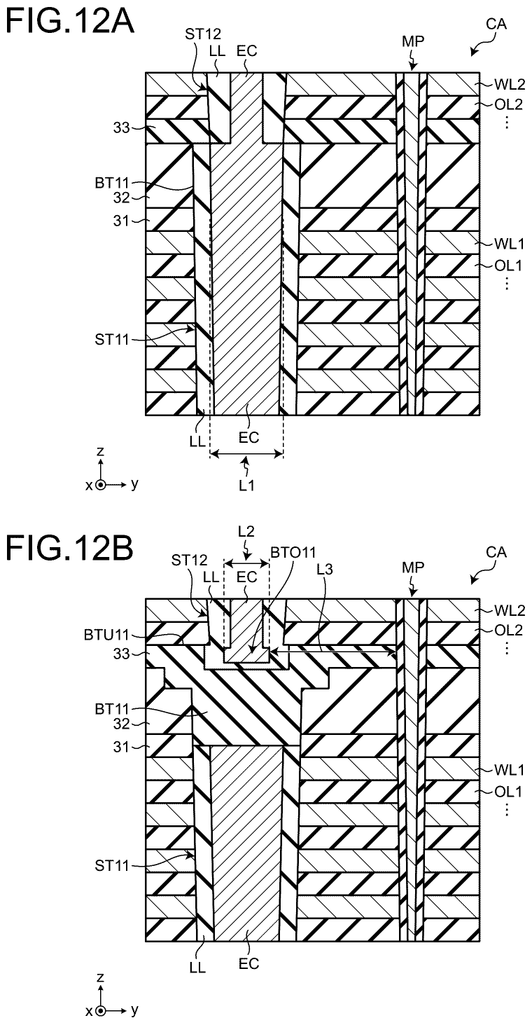

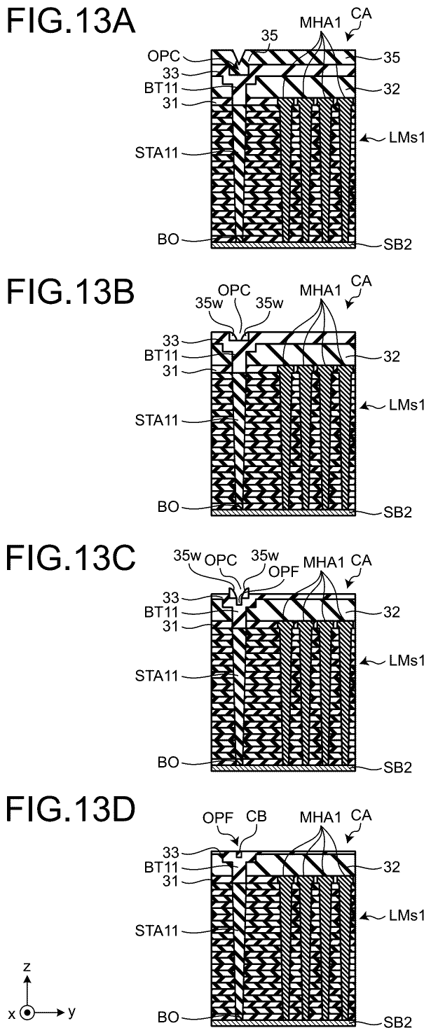

Next, a semiconductor memory device according to a modification example of the first embodiment will be described with reference to FIGS. 12A to 13D. The semiconductor memory device according to the modification example is different from the above-described first embodiment in the width in the y direction of the conductive member EC formed in a first bridging member BT11.

FIGS. 12A and 12B are cross-sectional views illustrating a detailed configuration of a cell array region CA of a semiconductor memory device 2 according to the modification example of the first embodiment. FIG. 12A is a yz cross-sectional view illustrating a part of a first platy member ST11 where the first bridging member BT11 is not formed, and FIG. 12B is a yz cross-sectional view illustrating a part of the first platy member ST11 where the first bridging member BT11 is formed.

As illustrated in FIG. 12A, the first platy member ST11 includes the conductive member EC and the liner layer LL that are formed in this order from the inside, and the conductive member EC in the upper end of the first platy member ST11 has a width L1 in the y direction. On the other hand, as illustrated in FIG. 12B, the first bridging member BT11 includes a lower structure BTB11 and an upper structure BTU11. The lower structure BTB11 has the same configuration as that of the lower structure BTB1 according to the above-described first embodiment. The upper structure BTU11 includes a junction part BTO11 different from the junction part BTO1 according to the above-described first embodiment. The upper structure BTU11 according to the modification example includes the junction part BTO11 where the conductive member EC and the liner layer LL are formed, and the conductive member EC in the junction part BTO11 has a width L2 in the y direction. The width L2 in the y direction of the conductive member EC formed in the first bridging member BT11 is less than or equal to the width L1 in the y direction of the upper end of the conductive member EC formed in the first platy member ST11. As a result, a wide distance L3 between the end in the y direction of the conductive member EC formed in the first bridging member BT11 and the memory pillar MP is ensured.

Note that, even in the modification example, the width L2 in the y direction of the conductive member EC formed in the first bridging member BT11 is preferably wider than the width in the y direction of the upper end of the conductive member EC formed in a second platy member ST12.

Next, a method of forming the cell array region CA according to the modification example will be described with reference to FIGS. 13A to 13D. FIGS. 13A to 13D are diagrams illustrating part of a procedure of the method of manufacturing the semiconductor memory device 2 according to the modification example of the first embodiment. Prior to the process of FIGS. 13A to 13D, even in the modification example, a process corresponding to the process of FIGS. 4Aa to 5Af of the above-described embodiment is performed. At this point, at the position where the first bridging member BT11 is formed, the lower structure BTB11 and the opening part OPC above the lower structure BTB11 are formed.

In FIG. 13A, on the insulating layer 33, a side wall layer 35 such as an amorphous silicon layer is deposited. The side wall layer 35 is deposited on the bottom surface and the side wall of the opening part OPC. When the side wall layer 35 is deposited on each of the above-described parts and reaches a predetermined film thickness, the opening part OPC is filled with the side wall layer 35.

In FIG. 13B, when the side wall layer 35 is etched back until the bottom part of the opening part OPC is exposed, the bottom surface of the opening part OPC is exposed, and part of the side wall layer 35 remains in the side surface of the opening part OPC to form a side wall 35w. Due to the side wall 35w that covers the side surface of the opening part OPC, the exposure width of the bottom surface of the opening part OPC in the y direction is narrower than the original width of the opening part OPC in the y direction.

In FIG. 13C, when the entire surface of the insulating layer 33 is etched back, the bottom surface of the opening part OPC exposed from the side wall 35w is etched and removed by using the side wall 35w as a mask. As a result, an opening part OPF extending in a depth direction from the bottom part of the opening part OPC is formed. In addition, the layer thickness of the insulating layer 33 decreases as a whole.

In FIG. 13D, the side wall 35w is removed by wet-etching, and a process corresponding to FIG. 5Ag is performed to fill the opening part OPE with the amorphous carbon layer CB. Next, by performing a process corresponding to the process of FIG. 6Ah and the subsequent drawings of the above-described embodiment, the first bridging member BT11 of the semiconductor memory device 2 according to the modification example is formed.

In the semiconductor memory device 2 according to the modification example, the width L2 in the y direction of the conductive member EC formed in the first bridging member BT11 is less than or equal to the width L1 in the y direction of the conductive member EC formed in the upper end of the first platy member ST11. As a result, the wide distance between the conductive member EC formed in the first bridging member BT11 and the memory pillar MP can be ensured, and thus the voltage resistance performance between the memory pillar MP and the conductive member EC of the first bridging member BT11 can be improved. In the semiconductor memory device 2 according to the modification example, in addition to the above-described effect, the same effect as that of the semiconductor memory device 1 according to the above-described first embodiment can be obtained.

### Second Embodiment

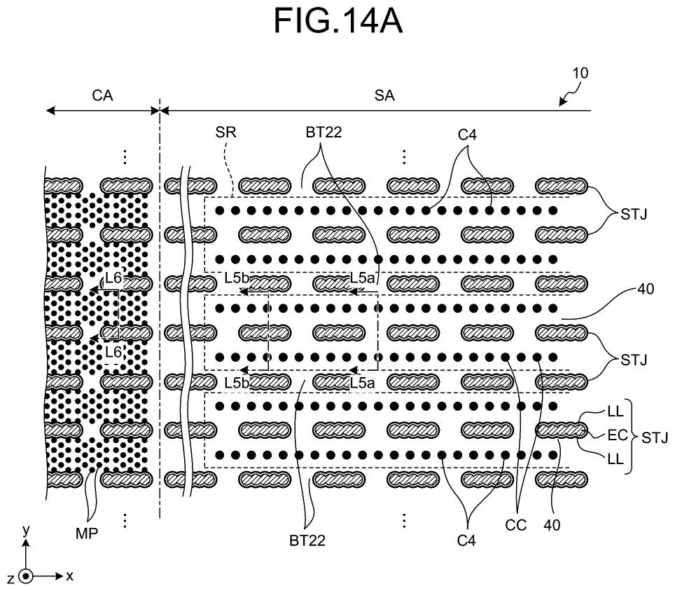

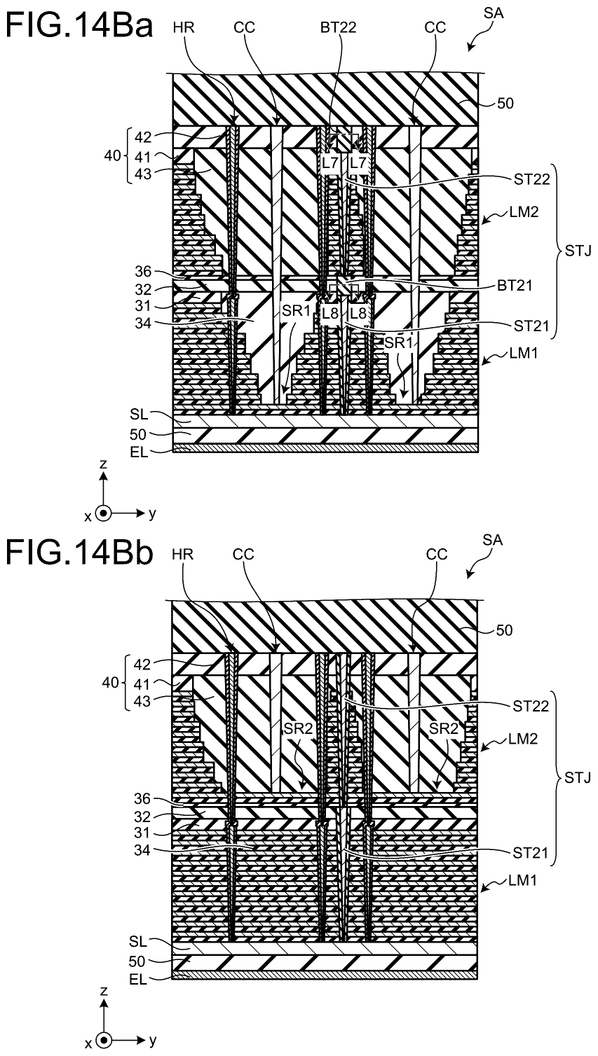

Next, a semiconductor memory device according to a second embodiment will be described with reference to FIGS. 14A to 20. The semiconductor memory device according to the second embodiment is different from the embodiment and the modification example described above in the shape of the platy member, the forming timing of the platy member, the material of the bridging member, and the like.

FIG. 14A is a partial top view illustrating a configuration example of a semiconductor memory device 10 according to the second embodiment. More specifically, FIG. 14A is a partial top view illustrating the schematic configuration of the semiconductor memory device 10 according to the second embodiment and is a diagram corresponding to the example of FIG. 1. In addition, FIGS. 14Ba to 14Bb are cross-sectional views illustrating the configuration example of the semiconductor memory device 10 according to the second embodiment. More specifically, FIG. 14Ba is a diagram illustrating a detailed configuration of the staircase region SA according to the second embodiment and is a yz cross-sectional view taken along line L5a-L5a of FIG. 14A. In addition, FIG. 14Bb is a yz cross-sectional view taken along line L5b-L5b of FIG. 14A.

As illustrated in FIG. 14A, in the cell array region CA and the staircase region SA, platy members STJ that divide each of the regions are formed. Each of the platy members STJ crosses the cell array region CA and the staircase region SA in the x direction, extends in the z direction in the drawing, and terminates in a source line (described below). In each of the platy members STJ, side surfaces on both sides in the y direction are formed a wave shape having periodicity in the x direction. In addition, the platy member STJ includes second bridging members BT22 that are intermittently provided in a longitudinal direction (x direction) of the platy member STJ.

As illustrated in FIG. 14Ba, the platy member STJ includes: a first platy member ST21 that extends in the x direction and penetrates the first stacked body LM1 and the insulating layers 31, 32, 34, and 36 in the z direction; and a second platy member ST22 that extends in the x direction, penetrates the second stacked body LM2 and the second interlayer insulating film 40 in the z direction, and is connected to an upper end of the first platy member ST21.

In addition, the first platy member ST21 and the second platy member ST22 include a first bridging member BT21 and a second bridging member BT22 in part of the upper ends, respectively. The first bridging member BT21 includes at least one among polysilicon and silicon carbonitride. The second bridging member BT22 includes at least one among silicon oxide, polysilicon, and silicon carbonitride. At this time, the first bridging member BT21 and the second bridging member BT22 may be formed of the same material or different materials.

On the other hand, as illustrated in FIG. 14Bb, in the other part of the upper ends of the first platy members ST21 and the second platy members ST22 extending in the x direction, the first bridging member BT21 and the second bridging member BT22 are not formed. The reason for this is that the first bridging members BT21 and the second bridging members BT22 are intermittently disposed in the x direction.

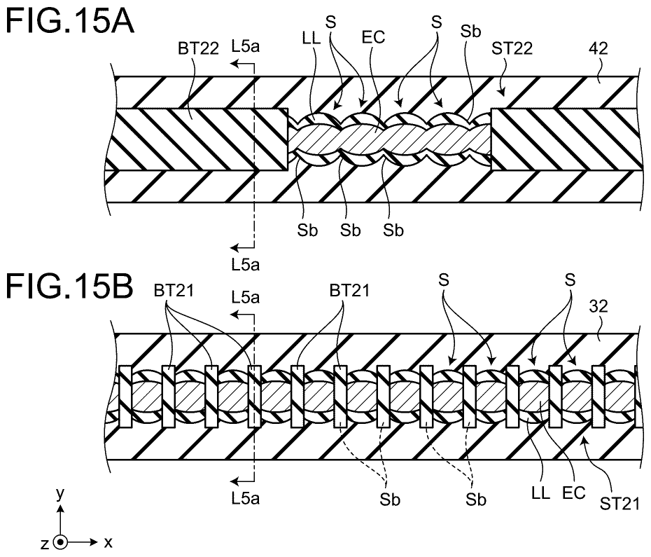

FIGS. 15A and 15B are diagrams illustrating a positional relationship between the first bridging member BT21 and a second bridging member BT22 according to the second embodiment. FIG. 15A is an xy cross-sectional view taken along line L7-L7 of FIG. 14Ba, and FIG. 15B is an xy cross-sectional view taken along line L8-L8 of FIG. 14Ba. Thus, FIGS. 15A and 15B are top views in an extending direction of the first platy member ST21 and the second platy member ST22. In addition, for example, as in the line L5a-L5a illustrated in FIG. 14A, the yz cross-section taken along the line L5a-L5a illustrated in FIGS. 15A and 15B corresponds to the surface illustrated in FIG. 14Ba.

As illustrated in FIGS. 15A and 15B, the side surfaces of the first platy member ST21 and the second platy member ST22 in the y direction are formed in a wave shape having periodicity in the x direction. Specifically, each of the first platy member ST21 and the second platy member ST22 includes a side surface part Sb having a shape that pillar-like members S having a substantially cylindrical shape that extend in the z direction are linked to each other in the x direction such that side surfaces on both sides of the individual pillar-like members S in the y direction are continuous in a wave shape. In addition, the liner layers LL of the first platy member ST21 and the second platy member ST22 are formed along the side walls having the above-described wave shape and thus also have the same wave shape. Further, the conductive members EC of the first platy member ST21 and the second platy member ST22 are filled inside the liner layers LL having a wave shape, and thus the side walls on both sides in the y direction have the same wave shape.

As illustrated in FIG. 15B, the first bridging members BT21 are disposed at regular intervals to cover linked points of the individual pillar-like members S in the first platy member ST21. On the other hand, as illustrated in FIG. 15A, the second bridging member BT22 is provided to continuously cover the pillar-like members S in the second platy member ST22.

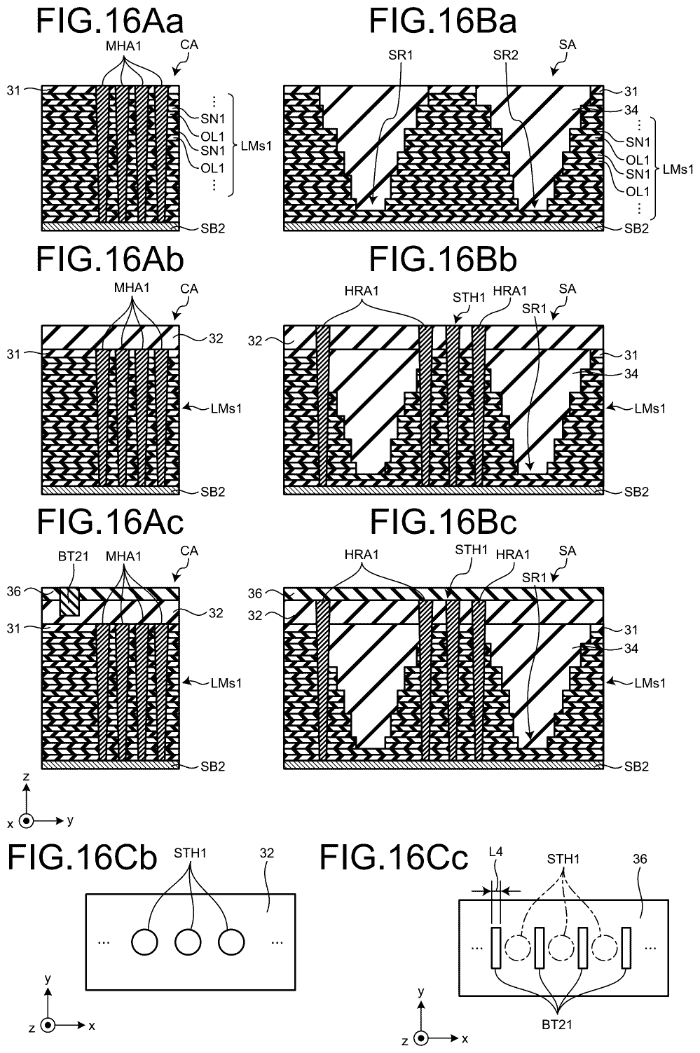

Hereinafter, a method of forming each of the configurations in the cell array region CA and the staircase region SA according to the second embodiment will be described with reference to FIGS. 16Aa to 20Bj. FIGS. 16Aa to 20Bj are diagrams illustrating part of a procedure of a method of manufacturing the semiconductor memory device 10 according to the second embodiment. FIGS. 16Aa to 20Aj are yz cross-sectional views taken along line L6-L6 of FIG. 14A. FIGS. 16Ba to 20Bj are yz cross-sectional views taken along the line L5a-L5a of FIG. 14A, and correspond to the cross-section illustrated in FIG. 14Ba. In addition, FIGS. 16Cb, 16Cc, 17Ce, and 19Ch are partial top views in the drawings corresponding to FIGS. 16Bb to 19Bh.

Prior to the process of FIGS. 16Aa and 16Ba, even in the second embodiment, a process corresponding to the process of FIGS. 4Aa and 4Ba of the first embodiment is performed. At this point, the first stacked body LMs1 is formed.

In FIG. 16Aa, the memory hole MHA1 that penetrates the first stacked body LMs1 and the insulating layer 31 is formed. Next, the memory hole MHA1 is embedded with amorphous carbon. On the other hand, in FIG. 16Ba, the hole HRA1 is not formed unlike the first embodiment.

Next, the insulating layer 32 is formed on the insulating layer 31 and the insulating layer 34, and a hole STH1 and the hole HRA1 that penetrate the first stacked body LMs1 and the insulating layers 31, 32, and 34 are formed as illustrated in FIG. 16Bb. The holes STH1 and HRA1 are circular holes that terminate in the substrate SB2. The diameters of the hole STH1 and the hole HRA1 are more than the diameter of the memory hole MHA1. In addition, the diameter of the hole STH1 may be substantially the same as the diameter of the hole HRA1 or may be slightly more than the diameter of the hole HRA1. As illustrated in FIG. 16Cb, holes STH1 are disposed away from each other at a predetermined interval in the x direction. Next, the hole STH1 and the hole HRA1 are embedded with amorphous carbon.

On the other hand, FIG. 16Ab illustrates a cross-section between the holes STH1 that are disposed away from each other at the predetermined interval in the x direction, and the holes STH1 are not provided in the cross-section of FIG. 16Ab. As illustrated in FIG. 16Cb, the holes STH1 are disposed away from each other at the predetermined interval in the x direction. Therefore, in the yz cross-section, the cross-section in which the holes STH1 are provided and the cross-section in which the holes STH1 are not provided appear as in FIGS. 16Ab and 16Bb. In addition, the hole STH1 is provided to form the slit STA1 and the first platy member ST21 that are subsequently formed.

Next, as illustrated in FIGS. 16Ac and 16Bc, an insulating layer 36 that covers the hole STH1, the hole HRA1, and the insulating layer 32 is formed. The insulating layer 36 is, for example, a silicon oxide layer. Next, a photoresist film (not illustrated) is applied to the insulating layer 36, and the photoresist film is opened such that parts between the holes STH1 are exposed. By using the photoresist film RF as a mask, the insulating layers 32 and 36 are dry-etched up to a depth that does not reach the lower surface of the insulating layer 31. The formed opening part is embedded with at least one among polysilicon and silicon carbonitride. As a result, the first bridging member BT21 is formed. As illustrated in FIG. 16Cc, the first bridging member BT21 is provided between the holes STH1, and is not disposed above the hole STH1. Thus, at the disposition position of the hole STH1 as in the cross-section illustrated in FIG. 16Bc, the first bridging member BT21 is not formed.

At this time, a width L4 in the x direction of the first bridging member BT21 provided between the holes STH1 is preferably small. The reason for this is that, as the width L4 decreases, the possibility that the first bridging member BT21 overlaps with the opening part of the hole STH1 decreases, and the possibility that the hole STH1 is substantially or completely covered with the first bridging member BT21 decreases. In a case where most or the entirety of the hole STH1 is covered with the first bridging member BT21, when a hole STH2 is subsequently formed on the hole STH1, the dry-etching of the first bridging member BT21 is inhibited, and the hole STH1 and the hole STH2 may not be linked to each other. As a result, the formation of the platy member STJ may be inhibited.

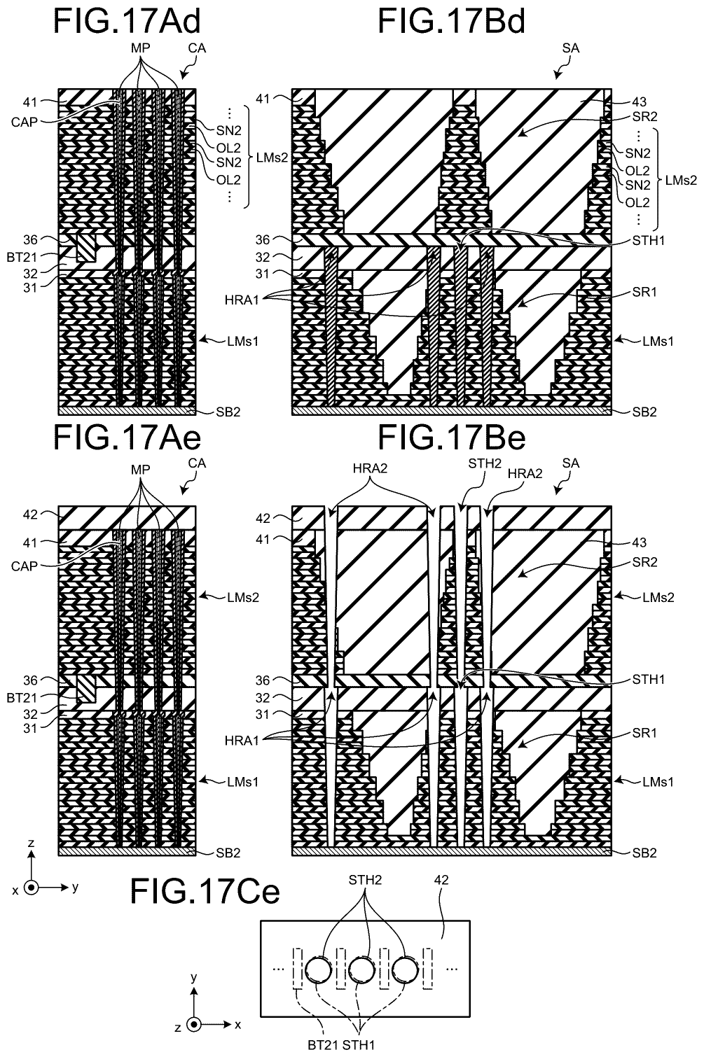

Next, the second stacked body LMs2 and the insulating layer 41 are formed in this order on the insulating layer 36, and the second staircase part SR2 and the insulating layer 43 that covers the second staircase part SR2 are formed as illustrated in FIG. 17Bd. As illustrated in FIG. 17Ad, a memory hole (not illustrated) that penetrates the second stacked body LMs2 and the insulating layer 41 and is connected to the memory hole MHA1 is formed, and the memory pillar MP is formed through a predetermined step.

Next, the insulating layer 42 that covers the insulating layers 41 and 43 is formed, and the hole STH2 and the hole HRA2 that penetrate the second stacked body LMs2 and the insulating layers 41 to 43 are formed as illustrated in FIG. 17Be. At this time, etching conditions of the hole STH2 and the hole HRA2 have high selectivity to polysilicon, silicon carbonitride, or the like forming the first bridging member BT21. However, as described above, the first bridging member BT21 is formed such that the hole STH1 is not completely blocked. Therefore, the hole STH2 and the hole HRA2 are connected to the upper ends of the hole STH1 and the hole HRA1, respectively. The diameters of the hole STH2 and the hole HRA2 are substantially the same as the diameters of the hole STH1 and the hole HRA1, respectively. The hole STH2 is provided to form the slit STA2 and the second platy member ST22 that are subsequently formed. On the other hand, the hole STH2 is not formed in the cross-section of FIG. 17Ae.

Next, the amorphous carbon filled in the hole STH1 and the hole HRA1 is removed by ashing treatment or the like.

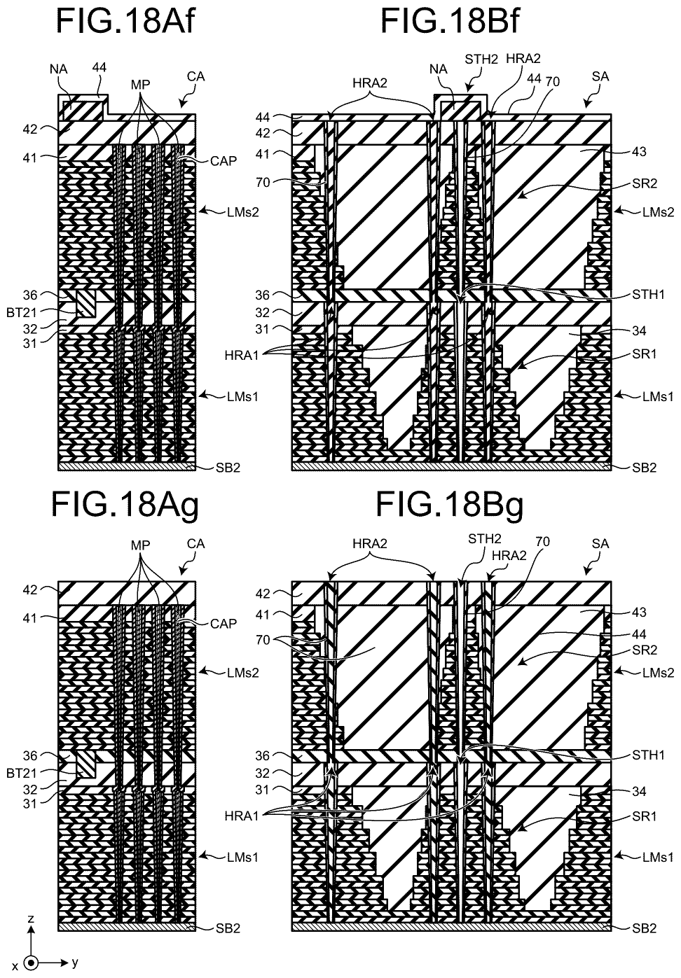

Next, as illustrated in FIG. 18Bf, an insulating layer 70 that covers side walls of the holes STH1 and STH2 and the holes HRA1 and HRA2 is formed. The insulating layer 70 is, for example, a silicon oxide layer. Next, a silicon nitride layer NA that covers the upper side of the hole STH2 is formed. The silicon nitride layer NA is formed with coverage to some extent that the inside of the hole STH2 is not filled with the silicon nitride layer NA. Next, the hole HRA1 and the hole HRA2 that are not covered with the silicon nitride layer NA are embedded with an insulating layer 44. The insulating layer 44 is, for example, a silicon oxide layer. The silicon nitride layer NA is formed in a plate shape that covers the holes STH2 of the staircase region SA and the cell array region CA. Therefore, even in a cross-section that the holes STH2 are not formed as in the cross-section of FIG. 18Af, the silicon nitride layer NA is formed, and the insulating layer 44 is further deposited.

In FIGS. 18Ag and 18Bg, the insulating layer 44 deposited on the insulating layer 42 is removed, for example, by CMP, and subsequently the silicon nitride layer NA is removed by the wet-etching process. As a result, the holes STH2 are opened in the surface of the insulating layer 42. At this time, the sacrificial layers SN1 and SN2 are protected from the above-described process liquid by the insulating layer 70.

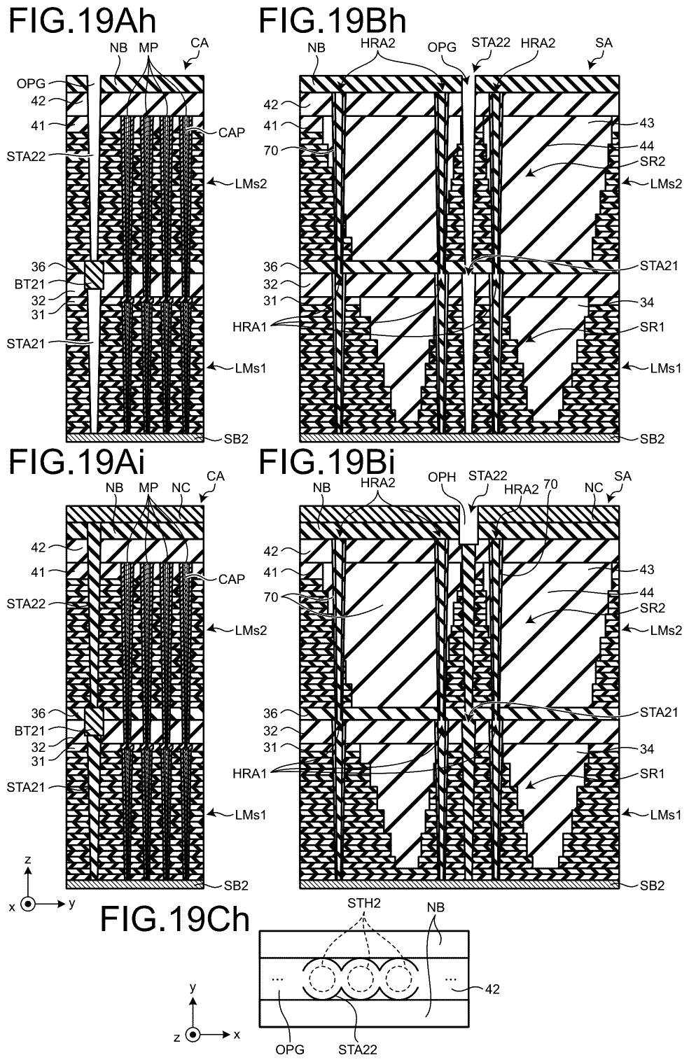

In FIGS. 19Ah and 19Bh, a silicon nitride layer NB including an opening part OPG above the hole STH2 is formed on the insulating layer 42, and the process liquid of the wet-etching process is caused to penetrate from the opening part OPG. The process liquid enters into the opening part OPG and penetrates into the lower end of the hole STH1 through the hole STH2. At this time, as described above, the first bridging member BT21 is formed such that the hole STH1 is not completely blocked. Therefore, the process liquid can penetrate from the lower end of the hole STH2 into the hole STH1. In the wet-etching process, by selecting the process liquid having high selectivity to polysilicon and silicon carbonitride, the dissolution of the first bridging member BT21 can be prevented.

As a result, the insulating layer 70, the sacrificial layers SN1 and SN2, the insulating layers OL1 and OL2, and the like exposed to the side walls of the holes STH1 and STH2 are dissolved such that the diameters of the holes STH1 and STH2 expand in the xy direction. As a result, as illustrated in FIG. 19Ch, the holes STH1 adjacent to each other and the holes STH2 adjacent to each other in the x direction are coupled to form slits STA21 and STA22 extending in the x direction.

In addition, as described above, the first bridging member BT21 is formed such that the hole STH1 is not completely blocked. Therefore, an upper end of the slit STA21 and a lower end of the slit STA22 are connected in a direction from the lower end of the hole STH2 to the hole STH1.

At this time, it is preferable to form the silicon nitride layer NB thick. As a result, the silicon nitride layer NB remains on the insulating layer 42 until the slits STA21 and STA22 are formed. Therefore, the insulating layer 42 can be protected from the above-described process liquid. In addition, the first bridging member BT21 of FIG. 19Ah has resistance to the above-described process liquid, and thus remains until the slits STA21 and STA22 are formed.

In FIGS. 19Ai and 19Bi, the slits STA21 and STA22 are embedded with amorphous carbon, and subsequently an insulating layer NC that covers the slits STA21 and STA22 and the silicon nitride layer NB is formed. The insulating layer NC is formed of at least any material among silicon oxide, polysilicon, and silicon carbonitride. Next, a photoresist film (not illustrated) is applied to the insulating layer NC, and the photoresist film is opened at a position overlapping with the slit STA22 in the z direction. The opening of the photoresist film extends in the x direction to overlap with the holes STH2 forming the slit STA22. By using the photoresist film as a mask, the insulating layer NC is dry-etched up to a depth that does not reach the lower surface of the insulating layer NC. Next, the photoresist film is removed by ashing treatment. At this time, in the opening of the insulating layer NC, part of the insulating layer NC remains on the upper surface of the slit STA22. Therefore, the amorphous carbon embedded in the slits STA21 and STA22 is protected by the insulating layer NC and is not eliminated by the ashing treatment.

Next, the residual film of the insulating layer NC is dry-etched until the amorphous carbon embedded in the slit STA22 is exposed. Next, by switching the etching gas and using the insulating layer NC in a region other than the opening part as a mask, the silicon nitride layer NB, the insulating layer 42, and the amorphous carbon are dry-etched up to a depth that does not reach the lower surface of the insulating layer 42. As a result, as illustrated in FIG. 19Bi, an opening part OPH is formed in an upper end of the slit STA22. On the other hand, in a region where the second bridging member BT22 is not formed as in the cross-section of FIG. 19Ai, the opening part OPH is not formed. At this time, by using the insulating layer NC that is a material different from the silicon nitride layer NB as a mask, for example, even when the switching timing of the etching gas after the exposure of the amorphous carbon deviates such that the etching with the gas before the switching is continued for a while even after the exposure of the amorphous carbon, the risk that the silicon nitride layer NB is excessively etched can be reduced.

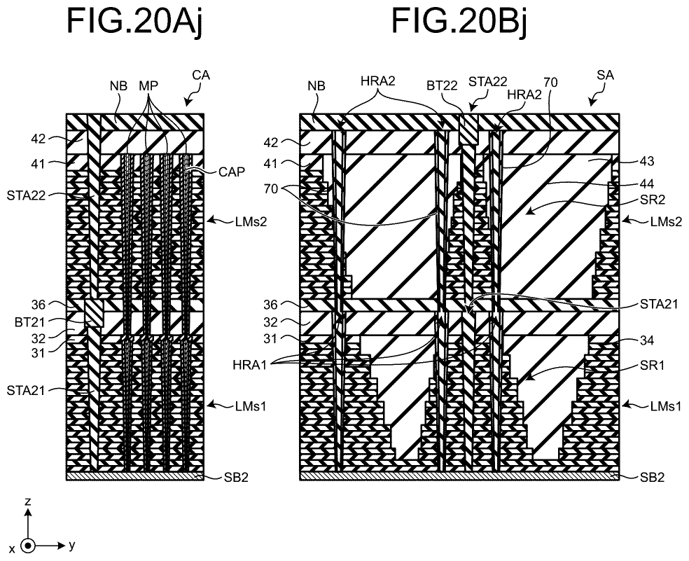

In FIG. 20Bj, the opening part OPH is embedded with same material as that of the insulating layer NC that is at least any one among silicon oxide, polysilicon, and silicon carbonitride. The deposit on the insulating layer NC is removed by, for example, CMP together with the insulating layer NC. As a result, the second bridging member BT22 is formed. On the other hand, FIG. 20Aj is a cross-section in which the second bridging member BT22 is not formed, as described above. In the part where the second bridging member BT22 is not formed, the amorphous carbon is exposed to the upper end of the slit STA2.

Next, although not illustrated, after FIGS. 20Aj and 20Bj, the silicon nitride layer NB is removed by dry-etching, and the amorphous carbon filled in the slits STA21 and STA22 is removed by ashing treatment or the like. Next, by performing a process corresponding to the process of FIGS. 9An and 9Bn and the subsequent drawings, the semiconductor memory device 10 according to the second embodiment is formed.

In the semiconductor memory device 10 according to the second embodiment, side surfaces of the first and second platy members ST21 and ST22 in the y direction have a wave shape having periodicity in the x direction. As described above, by configuring the first and second platy members ST21 and ST22 such that the holes STH1 and STH2 are linked and the side surfaces in the y direction have a wave shape, the holes STH1 and STH2 as bases for forming the first and second platy members ST21 and ST22 and the holes HRA1 and HRA2 as bases for forming the pillar-like members HR can be collectively formed.

Here, the memory holes MHA1 and MHA2 are processed under etching conditions suitable for processing the first and second stacked bodies LMs1 and LMs2 in which the sacrificial layers SN1 and SN2 and the insulating layers OL1 and OL2 are stacked. On the other hand, when the slits that penetrate not only the first and second stacked bodies LMs1 and LMs2 but also the first and second interlayer insulating films 30 and 40 are formed, for example, as in the slits STA1 and STA2 according to the first embodiment, etching condition different from the etching conditions of the memory holes MHA1 and MHA2 are required. In addition, the pillar-like members HR serve as supports of first and second stacked bodies LMs1 and LMs2 during the replacement process and do not contribute to the function of the semiconductor memory device 10. Therefore, accurate processing is not required unlike the memory holes MHA1 and MHA2.

Accordingly, by independently forming the memory holes MHA1 and MHA2 for which the first and second stacked bodies LMs1 and LMs2 are required to be accurately processed and forming the holes STH1 and STH2 for processing the first and second platy members ST21 and ST22 in parallel with the formation of the holes HRA1 and HRA2 for processing the pillar-like members HR, the manufacturing load of the semiconductor memory device 10 can be reduced, and the manufacturing cost can be reduced.

In the present embodiment, the first bridging member BT21 includes, for example, at least one material among polysilicon and silicon carbonitride, and the second bridging member BT22 includes, for example, at least any material among silicon oxide, polysilicon, and silicon carbonitride. However, the materials adopted as the first bridging member BT21 and the second bridging member BT22 are not limited to the above-described examples. Any combination can be adopted as long as the first bridging member BT21 has resistance to the process liquid used for forming the slits STA21 and STA22.

### First Modification Example

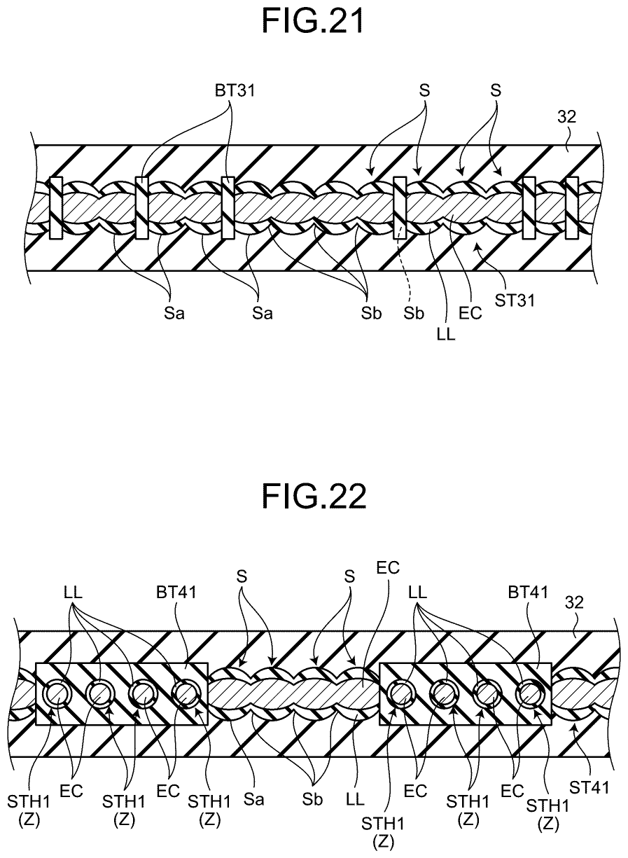

In a configuration of a first modification example of the second embodiment, a first platy member ST31 and a first bridging member BT31 are used instead of the first platy member ST21 and the first bridging member BT21 according to the second embodiment. FIG. 21 is a diagram illustrating a disposition example of the first bridging member BT31 according to the first modification example of the second embodiment. The first bridging members BT31 are provided on the upper end of the first platy member ST31 at an interval different from that of the first bridging members BT21.

As illustrated in FIG. 21, the first bridging member BT31 is constituted by multiple bridging members BT31 arranged in the x direction. At least part of these bridging members BT31 are disposed at a different interval. Specifically, in one example, the first bridging member BT31 may be disposed to cover part of the upper ends of the first platy member ST31 while interposing some of the pillar-like members S, instead of being disposed at regular intervals to cover each of the linked points of the individual pillar-like members S.

In this way, by appropriately varying the disposition density of the first bridging members BT31 depending on the bridging strength required for the first bridging members BT31, the first bridging members BT31 are not excessively formed, the manufacturing load of the semiconductor memory device 10 can be reduced, and the manufacturing cost can be reduced.

### Second Modification Example

In the above-described second embodiment, the hole STH2 and the hole HRA2 are formed using the etching conditions having selectivity to the first bridging member BT21. However, the hole STH2 and the hole HRA2 may be formed using etching conditions not having selectivity to the first bridging member BT21.

In this case, during the initial formation of the first bridging member BT21, the first bridging member BT21 may be formed to block the upper end of the hole STH1. The reason for this is that when the hole STH2 is formed at a position overlapping with the hole STH1 in the z direction, the lower end of the hole STH2 penetrates the first bridging member BT21 blocking the upper end of the hole STH1 and is connected to the hole STH1.

In a configuration of a second modification example of the second embodiment, a first platy member ST41 and a first bridging member BT41 are used instead of the first platy member ST21 and the first bridging member BT21 according to the second embodiment. FIG. 22 is a diagram illustrating a disposition example of the first bridging member BT41 according to the second modification example. The first bridging member BT41 also covers not only the linked points of the pillar-like members S and the pillar-like members S in the upper end of the first platy member ST41.

As illustrated in FIG. 22, the first bridging member BT41 is disposed to stride over some of the pillar-like members S. Here, the hole STH1 in the layer of the first bridging member BT41 is not linked in the x direction even after the process of linking the hole STH1 and the hole STH2. The reason for this is that the material forming the first bridging member BT41 is not dissolved in the wet-etching process of linking the hole STH1 and the hole STH2. Accordingly, after the pillar-like members S including the liner layer LL and the conductive member EC inside the liner layer LL are formed, parts of the hole STH1 extending inside of the layer of the first bridging member BT41 becomes pillar-like members Z that are not linked to each other. The pillar-like member Z includes the liner layer LL and the conductive member EC inside the liner layer LL as in the pillar-like member S. Note that, unlike the liner layers LL and the conductive members EC of the pillar-like members S, the liner layers LL of the pillar-like members Z independently have a closed annular shape, and the conductive members EC are independently present in the annular shapes of the liner layers LL. In addition, a lower end of the pillar-like member Z is connected to the first platy member ST21, and an upper end of the pillar-like member Z is connected to a lower end of the second platy member ST22.

In this way, by adopting the etching condition not having selectivity to the first bridging member BT21 as the processing conditions for the hole STH2 and the hole HRA2, the alignment accuracy of the first bridging member BT21 relative to the hole STH1 can be reduced, the manufacturing load of the semiconductor memory device 10 can be reduced, and the manufacturing cost can be reduced.

In addition, in the first bridging member BT41 disposed to stride over the plurality of pillar-like members S, the installation volume is larger than that of the first bridging member BT21 according to the second embodiment that covers each of the side surface parts Sb. Therefore, the support strength of the insulating layer 32 is improved. As a result, deflection and inclination of the layer can be further suppressed.

The disposition examples of the first bridging member BT31 and the first bridging member BT41 illustrated in FIGS. 20 and 21 are merely exemplary, and the present embodiment is not limited thereto. The lengths of the first bridging member BT31 and the first bridging member BT41 in the x direction, the intervals thereof adjacent to each other, the numbers thereof, and the like may be appropriately determined.

### Other Embodiments

In the first and second embodiments and the modification examples thereof described above, the semiconductor memory device has the 2-tier stacked structure including the first stacked body LM1 and the second stacked body LM2. However, the semiconductor memory device may have a stacked structure of 3-tier or higher. In the multi-tier type semiconductor memory device, the number of layers stacked in the conductive layers WL stacked can be easily increased.

In the first and second embodiments and the modification examples thereof described above, the platy members STL and STJ include the conductive member EC, but the present embodiments are not limited thereto. In one example, the platy members STL and STJ may be formed of an insulating material such as silicon oxide as a whole. In this case, the platy members STL and STJ do not have a function as a source line contact.

Specifically, the first platy member ST21 extends in the x direction, penetrates the stacked body LM1 in the z direction, and includes silicon oxide, and the second platy member ST22 extends in the x direction, penetrates the stacked body LM2 in the z direction, is connected to the upper end of the first platy member ST21, and includes silicon oxide. The first bridging member BT21 is provided on the upper end of the first platy member ST21, includes a material different from silicon oxide, and connects the first interlayer insulating films 30 on both sides of the first platy member ST21. The silicon oxide is an example of the first insulating material.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which first conductive layers and first insulating layers are alternately stacked one by one, the first conductive layers including a first staircase part in a staircase shape extending in a first direction intersecting with a stacking direction of the first conductive layers;
a first interlayer insulating film covering the first staircase part;
a second stacked body in which second conductive layers and second insulating layers are alternately stacked one by one, the second stacked body being provided above the first stacked body, the second conductive layers including a second staircase part in a staircase shape continuous to the first staircase part in the first direction;
a second interlayer insulating film covering the second staircase part;
a first platy member extending in the first direction and penetrating the first stacked body in the stacking direction;
a second platy member extending in the first direction and penetrating the second stacked body in the stacking direction, the second platy member being connected to an upper end of the first platy member;
a first bridging member provided on the upper end of the first platy member, the first bridging member connecting the first interlayer insulating films on both sides of the first platy member; and
a second bridging member provided on an upper end of the second platy member, the second bridging member connecting the second interlayer insulating films on both sides of the second platy member,
wherein lower ends of the first and second bridging members are positioned above uppermost first and second conductive layers in the first and second stacked bodies, respectively.

2. The semiconductor memory device according to claim 1, wherein
the first and second platy members and at least part of the first bridging member each include a conductive member including a conductive material, and
a width in a second direction of the conductive member in the first bridging member is less than or equal to a width in the second direction of the conductive member in the upper end of the first platy member, the second direction being a direction intersecting with the first direction and the stacking direction.

3. The semiconductor memory device according to claim 2, wherein side surfaces in the second direction of the first and second platy members have a wave shape with periodicity in the first direction.

4. The semiconductor memory device according to claim 3, wherein the first and second platy members each include pillar-like members extending in the stacking direction, the pillar-like members being linked to each other in the first direction.

5. The semiconductor memory device according to claim 3, wherein
the first bridging member includes at least one material among polysilicon and silicon carbonitride, and
the second bridging member includes at least any material among silicon oxide, polysilicon, and silicon carbonitride.

6. The semiconductor memory device according to claim 1, wherein the first bridging member is constituted by multiple bridging members arranged in the first direction at intervals being partly different.

7. The semiconductor memory device according to claim 1, wherein at least part of the first bridging member does not overlap in the stacking direction with at least part of the second bridging member.

8. The semiconductor memory device according to claim 4, wherein
the first bridging member is provided to stride over the pillar-like members of the first and second platy members in the first direction, and
the first bridging member includes pillar-like members connected to the first and second platy members in the stacking direction and not linked to each other.

9. The semiconductor memory device according to claim 2, wherein the width in the second direction of the conductive member in the first bridging member is wider than a width in the second direction of the conductive member in a lower end of the second platy member.

10. A semiconductor memory device comprising:
a first stacked body in which first conductive layers and first insulating layers are alternately stacked one by one, the first conductive layers including a first staircase part in a staircase shape extending in a first direction intersecting with a stacking direction of the first conductive layers;
a first interlayer insulating film covering the first staircase part;
a second stacked body in which second conductive layers and second insulating layers are alternately stacked one by one, the second stacked body being provided above the first stacked body, the second conductive layers including a second staircase part in a staircase shape continuous to the first staircase part in the first direction;
a second interlayer insulating film covering the second staircase part;
a first platy member extending in the first direction and penetrating the first stacked body in the stacking direction, the first platy member including a first insulating material;
a second platy member extending in the first direction and penetrating the second stacked body in the stacking direction, the second platy member being connected to an upper end of the first platy member, the second platy member including the first insulating material; and
a bridging member provided on the upper end of the first platy member, the first bridging member connecting the first interlayer insulating films on both sides of the first platy member, the first bridging member including a material different from the first insulating material, wherein
side surfaces in a second direction of the first and second platy members have a wave shape with periodicity in the first direction, the second direction being a direction intersecting with the first direction and the stacking direction, and
a lower end of the bridging member is positioned above an uppermost first conductive layer in the first stacked body.

11. A method of manufacturing a semiconductor memory device, the method comprising:
forming a first stacked body in which first insulating layers and second insulating layers are alternately stacked one by one, the second insulating layers including a first staircase part processed in a staircase shape extending in a first direction intersecting with a stacking direction of the second insulating layers;
forming a first interlayer insulating film to cover the first staircase part;
forming a first groove, the first groove penetrating the first stacked body in the stacking direction and extending in the first direction;
forming a first bridging member in an upper end of the first groove, the first bridging member connecting the first interlayer insulating films on both sides of the first groove, the first bridging member including a lower end positioned above the second insulating layer;
forming a second stacked body in which third insulating layers and fourth insulating layers are alternately stacked one by one in the stacking direction, the second stacked body being formed above the first stacked body, the fourth insulating layers including a second staircase part processed in a staircase shape continuous to the first staircase part in the first direction;
forming a second interlayer insulating film to cover the second staircase part;
forming a second groove, the second groove penetrating the second stacked body in the stacking direction and extending in the first direction; and
forming a second bridging member in an upper end of the second groove, the second bridging member connecting the second interlayer insulating films on both sides of the second groove, the second bridging member including a lower end positioned above the fourth insulating layer.

12. The method according to claim 11, wherein the forming of the first bridging member includes:
forming a first opening part in the upper end of the first groove, the first opening part having a width in a second direction wider than a width in the second direction of the first groove, the second direction intersecting with the first direction and the stacking direction;
depositing an insulating layer on a bottom surface and a side wall of the first opening part; and
forming a second opening part inside the first opening part, the second opening part having a width in the second direction less than or equal to a width in the second direction of the upper end of the first groove.

13. A method of manufacturing a semiconductor memory device, the method comprising:
forming a first stacked body in which first insulating layers and second insulating layers are alternately stacked one by one, the second insulating layers including a first staircase part processed in a staircase shape extending in a first direction intersecting with a stacking direction of the second insulating layers;
forming a first interlayer insulating film to cover the first staircase part;
forming first holes penetrating the first stacked body in the stacking direction, the first holes being arranged at a predetermined interval in the first direction;
forming a first bridging member between the first holes, the first bridging member connecting the first interlayer insulating films on both sides, the first bridging member including a lower end positioned above the second insulating layer;
forming a second stacked body in which third insulating layers and fourth insulating layers are alternately stacked one by one in the stacking direction, the second stacked body being formed above the first stacked body, the fourth insulating layers including a second staircase part processed in a staircase shape continuous to the first staircase part in the first direction;
forming a second interlayer insulating film to cover the second staircase part;
forming second holes penetrating the second stacked body in the stacking direction, the second holes being arranged at a predetermined interval in the first direction;
forming a first groove and a second groove each extending in the first direction, the forming being performed by
expanding diameters of the first and second holes in the first direction and a second direction intersecting with the first direction and the stacking direction, and
coupling the first holes adjacent to each other and the second hole adjacent to each other in the first direction, respectively; and
forming a second bridging member in an upper end of the second groove, the second bridging member connecting the second interlayer insulating films on both sides of the second groove, the second bridging member including a lower end positioned above the fourth insulating layer.

14. The method according to claim 13, wherein
the first bridging member includes at least one material among polysilicon and silicon carbonitride, and
the second bridging member includes at least any material among silicon oxide, polysilicon, and silicon carbonitride.

15. The method according to claim 13, wherein the forming of the first bridging member includes differentiating at least part of intervals at which multiple bridge parts constituting the first bridging member are arranged.

16. The method according to claim 13, wherein the forming of the second bridging member includes providing no overlap in the stacking direction between at least part of the second bridging member and at least part of the first bridging member.

17. The method according to claim 11, wherein the forming of the first bridging member includes:
forming a first opening part in the upper end of the first groove, the first opening part having a width in a second direction wider than a width in the second direction of the first groove, the second direction intersecting with the first direction and the stacking direction;
depositing an insulating layer on a bottom surface and a side wall of the first opening part; and
forming a second opening part inside the first opening part, the second opening part having a width in the second direction wider than a width in the second direction of a lower end of the second groove.
